(19) United States
(12) Patent Application Publication
(10) Pub. No.: US 2025/0155808 A1
(43) Pub. Date: May 15, 2025

(54) RESIST COMPOSITION AND METHOD OF FORMING RESIST PATTERN

(71) Applicant: ZEON CORPORATION, Chiyoda-ku, Tokyo (JP)

(72) Inventor: Makoto FUJIMURA, Chiyoda-ku, Tokyo (JP)

(73) Assignee: ZEON CORPORATION, Chiyoda-ku, Tokyo (JP)

(21) Appl. No.: 18/840,074

(22) PCT Filed: Mar. 22, 2023
(86) PCT No.: PCT/JP2023/011309

§ 371 Date: Aug. 21, 2024

(30) Foreign Application Priority Data
Mar. 31, 2022 (JP) 2022-061239

(51) Int. Cl. G03F 7/039; G03F 7/20

(52) U.S. Cl. CPC G03F 7/039; G03F 7/2004

(57) ABSTRACT

Provided is a resist composition in which a cross-linker that reacts in response to ionizing radiation or non-ionizing radiation having a wavelength of 300 nm or less is compounded.

### TECHNICAL FIELD

The present disclosure relates to a resist composition and a method of forming a resist pattern.

### BACKGROUND

Resist compositions that contain a polymer and a solvent are conventionally used to form fine patterns through irradiation with ionizing radiation, such as an electron beam or extreme ultraviolet light (EUV), or non-ionizing radiation, inclusive of short-wavelength light such as ultraviolet light, in fields such as semiconductor production.

Attempts have previously been made to compound cross-linkers in resist compositions from viewpoints such as increasing the sensitivity of an obtained resist and increasing the strength of an obtained resist pattern (for example, refer to Patent Literature (PTL) 1 to 4).

### CITATION LIST

### Patent Literature

PTL 1: JP-S56-019044A
PTL 2: JP-S56-088134A
PTL 3: JP2000-321791A
PTL 4: JP2004-279694A

### SUMMARY

### Technical Problem

In recent years, there has been demand for resist compositions to have wide tolerance with respect to the magnitude of exposure dose in an exposure step (i.e., to have a wide exposure margin). There is also demand, of course, for a resist pattern to be clear and have few defects. However, resist compositions that have previously been studied, such as described above, leave room for improvement in terms of simultaneously widening the exposure margin and clarifying an obtained resist pattern.

Accordingly, one object of the present disclosure is to provide a resist composition and a method of forming a resist pattern that have a wide exposure margin and enable the formation of a clear resist pattern having few defects.

### Solution to Problem

The inventor conducted diligent investigation with the aim of solving the problems set forth above. As a result, the inventor made a new discovery that by compounding a cross-linker that reacts in response to ionizing radiation or non-ionizing radiation having a wavelength of 300 nm or less in a resist composition, it is possible to achieve a wide resist film exposure margin and to form a clear resist pattern having few defects. In this manner, the inventor completed the present disclosure.

Specifically, with the aim of advantageously solving the problems set forth above, [1] a presently disclosed resist composition comprises: a cross-linker that reacts in response to ionizing radiation or non-ionizing radiation having a wavelength of 300 nm or less; a solvent; and a polymer. Through a resist composition that contains this prescribed cross-linker, the exposure margin of a formed resist film is wide, and an obtained resist pattern is clear with few defects.
[2] In the resist composition according to the foregoing [1], the polymer is preferably a main chain scission-type polymer. When the polymer is a main chain scission-type polymer, an even better exposure margin widening effect and pattern clarifying effect can be obtained.
[3] In the resist composition according to the foregoing [1] or [2], the polymer is preferably a copolymer including:
a monomer unit (A) represented by general formula (I), shown below,

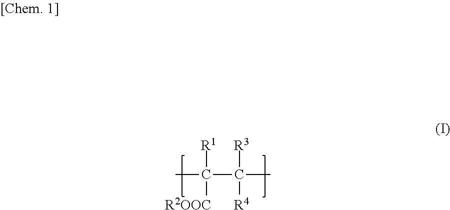

where, in general formula (I), R¹ is a halogen atom or a halogen atom-substituted alkyl group, R² is a hydrogen atom or an organic group including not fewer than 0 and not more than 11 fluorine atoms, and R³ and R⁴ are each a hydrogen atom, a halogen atom, an unsubstituted alkyl group, or a halogen atom-substituted alkyl group and may be the same as or different from each other; and
a monomer unit (B) represented by general formula (II), shown below,

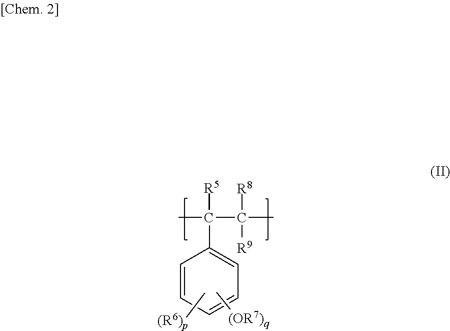

where, in general formula (II), R⁵, R⁶, R⁸, and R⁹ are each a hydrogen atom, a halogen atom, an unsubstituted alkyl group, or a halogen atom-substituted alkyl group and may be the same as or different from one another, R⁷ is a hydrogen atom, an unsubstituted alkyl group, or a halogen atom-substituted alkyl group, p and q are each an integer of not less than 0 and not more than 5, and p+q=5.

When the resist composition contains a copolymer including specific monomer units in this manner, the resolution of an obtained resist pattern can be increased.
[4] In the resist composition according to any one of the foregoing [1] to [3], the cross-linker preferably includes an unsaturated bond. By compounding a cross-linker that includes an unsaturated bond, it is possible to obtain an even better exposure margin widening effect and pattern clarifying effect.
[5] In the resist composition according to the foregoing [4], the cross-linker preferably includes not fewer than 1 and not more than 10 of the unsaturated bond. By compounding a cross-linker in which the number of unsaturated bonds is not less than 1 and not more than 10, it is possible to obtain an even better exposure margin widening effect and pattern clarifying effect.
[6] In the resist composition according to the foregoing [4] or [5], the unsaturated bond of the cross-linker is preferably an unsaturated bond included in a vinyl group, a (meth)acrylate group, or an allyl group. By compounding a cross-linker that includes any of these prescribed unsaturated bond-containing functional groups, it is possible to obtain an even better exposure margin widening effect and pattern clarifying effect. Note that in the present specification, “(meth)acrylate” indicates “acrylate” or “methacrylate”.
[7] In the resist composition according to any one of the foregoing [1] to [6], the cross-linker is preferably included in a proportion of not less than 1 part by mass and not more than 60 parts by mass relative to 100 parts by mass of the polymer. When the amount of the cross-linker is within this range, an even better exposure margin widening effect and pattern clarifying effect can be obtained, and the resolution of an obtained resist pattern can be increased.
[8] Moreover, with the aim of advantageously solving the problems set forth above, a presently disclosed method of forming a resist pattern comprises: performing resist film formation by applying a resist composition containing a cross-linker that reacts in response to ionizing radiation or non-ionizing radiation having a wavelength of 300 nm or less, a solvent, and a polymer onto a substrate to obtain a coating layer, and removing the solvent from the coating layer to form a resist film; and performing exposure by exposing the resist film formed in the resist film formation using ionizing radiation or non-ionizing radiation having a wavelength of 300 nm or less as exposure light and causing a cross-linking reaction to proceed through the cross-linker while forming a latent pattern. The method of forming a resist pattern in which a cross-linking reaction through the cross-linker and formation of a latent pattern are caused to proceed concurrently during exposure results in a wide exposure margin during exposure and the formation of a resist pattern that is clear and has few defects.
[9] In the method of forming a resist pattern according to the foregoing [8], it is preferable that the polymer is a main chain scission-type polymer and that the cross-linking reaction and a main chain scission reaction of the polymer proceed concurrently in the exposure. The method of forming a resist pattern that includes this exposure results in an even wider exposure margin during exposure and the formation of a resist pattern that is clear and has even fewer defects.

### Advantageous Effect

According to the present disclosure, it is possible to provide a resist composition and a method of forming a resist pattern that have a wide exposure margin and enable the formation of a clear resist pattern having few defects.

### DETAILED DESCRIPTION

The following provides a detailed description of embodiments of the present disclosure.

The presently disclosed resist composition and method of forming a resist pattern can suitably be used in formation of a resist pattern in a production process of a printed board such as a build-up board, a semiconductor, a photomask, or a mold, for example, without any specific limitations. Note that the presently disclosed resist composition can suitably be used in the presently disclosed method of forming a resist pattern.

### (Resist Composition)

A feature of the presently disclosed resist composition is that it contains a cross-linker that reacts in response to ionizing radiation or non-ionizing radiation having a wavelength of 300 nm or less, a solvent, and a polymer. The resist composition containing this prescribed cross-linker results in a formed resist film having a wide exposure margin and an obtained resist pattern being clear and having few defects. Although the reason for this is not clear, it is presumed to be as follows.

In the case of a cross-linker that has a property of enabling a cross-linking reaction to proceed with ionizing radiation or non-ionizing radiation having a wavelength of 300 nm or less (i.e., radiation used as exposure light in an exposure step) as a trigger, this cross-linker does not cause a cross-linking reaction prior to the exposure step, but rather initiates the cross-linking reaction when a trigger of exposure light is imparted in the exposure step. On the other hand, formation of a latent pattern proceeds in the exposure step as a result of a resist film being irradiated with exposure light. Specifically, in formation of a latent pattern, a difference in terms of solvent solubility of a polymer forming the resist film is created between an exposed portion and a non-exposed portion in the resist film. In other words, the formation of a latent pattern results in the formation of a portion where polymer having comparatively poor solubility in a solvent is present (hereinafter, referred to as a “poorly soluble portion A”) and a portion where polymer having comparatively high solubility in a solvent is present (hereinafter, referred to as a “highly soluble portion B”). In a situation in which the exposure dose in the exposure step is comparatively small (i.e., in a “low-dose situation”), it may be difficult to create a sufficient difference in terms of solubility between the “poorly soluble portion A” and the “highly soluble portion B”. In such a situation, the further inclusion of the aforementioned specific cross-linker in the resist film, in addition to the polymer, makes it possible to enhance the poor solubility of the poorly soluble portion A through a reaction among the cross-linker and a reaction between the cross-linker and the polymer forming the poorly soluble portion A. As a result, the creation of a difference in terms of solubility between the “poorly soluble portion A” and the “highly soluble portion B” can be promoted well even in a situation in which the exposure dose in the exposure step is comparatively small. In the case of EUV lithography, for example, a portion that is affected by flare due to an EUV exposure tool or leaked light due to a mask pattern may be a region that receives “low-dose” irradiation. Moreover, in the case of electron beam lithography, for example, a portion that is affected by scattering (blur) of electrons such as forward scattering due to an electron beam lithography tool or backscattering due to a substrate may be a region that receives “low-dose” irradiation. In such regions that may receive “low-dose” irradiation, reaction of the cross-linker can enhance poor solubility of the poorly soluble portion A as previously described, and, as a result, is thought to enable the formation of a clear resist pattern. Moreover, in a situation in which the exposure dose in the exposure step is comparatively large (i.e., in a “high-dose situation”), a sufficient difference in terms of solubility is created between the “poorly soluble portion A” and the “highly soluble portion B” through an exposure dose of a certain level, but an exposure dose exceeding a certain level may result in a condition in which solubility of the “highly soluble portion B” is reduced. In response, the specific cross-linker is thought to impede an increase of molecular weight of the polymer in the “highly soluble portion B” and enable the formation of a clear resist pattern even in a high-dose situation. For example, in a case in which the polymer is a chemical amplification-type polymer for which a catalyst reaction is instigated in a subsequent post exposure bake step due to acid of an acid generator that is generated with exposure light as a trigger, the presence of the cross-linker is thought to result in the cross-linker being taken in by the poorly soluble portion A, thereby enabling a larger difference in terms of solubility between the poorly soluble portion A and the highly soluble portion B and the formation of a clear resist pattern. Moreover, in a case in which the polymer is a main chain scission-type polymer that undergoes polymer chain scission to form a low molecular weight product having higher solubility with exposure light as a trigger, it is thought to be possible to impede the low molecular weight product that is formed through main chain scission from bonding together again to increase the molecular weight and thereby become poorly soluble. This is because, in general, an increase of molecular weight can be suppressed and poor solubility is less likely to arise when a low molecular weight product bonds with the cross-linker than when low molecular weight products bond together once again.

### <Cross-linker>

A cross-linker that reacts in response to ionizing radiation or non-ionizing radiation having a wavelength of 300 nm or less is used as the cross-linker. More specifically, a cross-linker that results in thickness reduction of less than 50% from pre-immersion thickness in a situation in which a film formed of the cross-linker is irradiated with specific radiation to place the film in a cross-linked state and is subsequently immersed for 1 minute in a solvent in which the cross-linker is soluble can be used as the cross-linker.

In addition to satisfying an essential attribute that a cross-linking reaction thereof proceeds with irradiation with ionizing radiation or non-ionizing radiation having a wavelength of 300 nm or less as a trigger, the cross-linker preferably also has a property that a cross-linking reaction thereof does not proceed in a drying step for solvent removal during formation of a resist film, which is typically accompanied by heating, for example.

From a viewpoint of obtaining an even better exposure margin widening effect and pattern clarifying effect, it is preferable that a compound including an unsaturated bond, and more specifically a carbon-carbon unsaturated bond in the molecular structure thereof is used as the cross-linker. Moreover, from a viewpoint of even further enhancing these effects and increasing the resolution of an obtained resist pattern, the number of unsaturated bonds included in the molecular structure of the cross-linker is preferably 1 or more, and more preferably 2 or more, and is preferably 10 or less, and more preferably 8 or less.

Furthermore, an unsaturated bond of the cross-linker is preferably an unsaturated bond that is included in a vinyl group, a (meth)acrylate group, or an allyl group. By compounding a cross-linker that includes any of these prescribed unsaturated bond-containing functional groups, it is possible to obtain an even better exposure margin widening effect and pattern clarifying effect and also to increase the resolution of an obtained resist pattern. Note that the cross-linker may include just any one of a vinyl group, a (meth)acrylate group, and an allyl group or may include a plurality thereof. The number of these functional groups that can be included in the cross-linker is preferably 1 or more, and more preferably 2 or more, and is preferably 10 or less, and more preferably 8 or less.

Examples of cross-linkers that can be used include the following compounds, but are not specifically limited thereto. Vinyl group-containing compounds, allyl group-containing compounds, acrylate compounds, methacrylate compounds, and isocyanurate compounds can be used.

Examples of vinyl group-containing compounds and allyl group-containing compounds include alkene compounds such as ethylene, propene, 1-butene, 2-butene, isobutene, 1-pentene, 1-hexene, and 1-octene; cyano group-containing unsaturated hydrocarbon compounds such as acrylonitrile, methacrylonitrile, α-chloroacrylonitrile, and α-cyanoethylacrylonitrile; monovinyl ether compounds such as vinyl ethyl ether, vinyl butyl ether, vinyl phenyl ether, vinyl 2-chloroethyl ether, 3,4-dihydro-2H-pyran, 2,3-dihydrofuran, 1,4-dioxene, ethylene glycol monovinyl ether, diethylene glycol monovinyl ether, and isopropenyl methyl ether; divinyl ether compounds having an aliphatic skeleton such as divinyl ether, ethylene glycol divinyl ether, diethylene glycol divinyl ether, triethylene glycol divinyl ether, tetraethylene glycol divinyl ether, polyethylene glycol divinyl ether, propylene glycol divinyl ether, dipropylene glycol divinyl ether, tripropylene glycol divinyl ether, polypropylene glycol divinyl ether, butanediol divinyl ether, neopentyl glycol divinyl ether, hexanediol divinyl ether, nonanediol divinyl ether, trimethylolpropane divinyl ether, ethylene oxide adduct of trimethylolpropane divinyl ether, pentaerythritol divinyl ether, and ethylene oxide adduct of pentaerythritol divinyl ether; trivinyl ether compounds having an aliphatic skeleton such as trimethylolpropane trivinyl ether and ethylene oxide adduct of trimethylolpropane trivinyl ether; tetravinyl ether compounds having an aliphatic skeleton such as pentaerythritol tetravinyl ether, ethylene oxide adduct of pentaerythritol tetravinyl ether, and di(trimethylolpropane) tetravinyl ether; other such polyfunctional vinyl ether compounds having an aliphatic structure such as dipentaerythritol hexavinyl ether; polyfunctional vinyl ether compounds having an alicyclic skeleton such as 1,4-cyclohexanediol divinyl ether and 1,4-cyclohexanedimethanol divinyl ether; polyfunctional vinyl ether compounds having an aromatic skeleton such as hydroquinone divinyl ether; vinyl ester compounds such as vinyl acetate, vinyl butyrate, isopropenyl butyrate, vinyl caprate, and vinyl benzoate; unsaturated alcohols such as allyl alcohol and cinnamyl alcohol; conjugated diene compounds such as 1,3-butadiene, isoprene, 1,3-pentadiene, 1,3-hexadiene, 1,3-cyclohexadiene, 1,3-cycloheptadiene, 1,3-cyclooctadiene, 2,5-dimethyl-2,4-hexadiene, and chloroprene; aromatic vinyl compounds such as styrene, 2-methylstyrene, 3-methylstyrene, 4-methylstyrene, 2,4,6-trimethylstyrene, 4-butylstyrene, 4-phenylstyrene, 4-fluorostyrene, 2,3,4,5,6-pentafluorostyrene, 4-chlorostyrene, 4-bromostyrene, 4-iodostyrene, 4-hydroxystyrene, 4-aminostyrene, 4-carboxystyrene, 4-acetoxystyrene, 4-cyanomethylstyrene, 4-chloromethylstyrene, 4-methoxystyrene, 4-nitrostyrene, sodium 4-styrenesulfonate, 4-styrenesulfonyl chloride, 4-vinylphenylboronic acid, α-methylstyrene, trans-β-methylstyrene, 2-methyl-1-phenylpropene, 1-phenyl-1-cyclohexene, β-bromostyrene, sodium β-styrenesulfonate, 2-vinylpyridine, 4-vinylpyridine, 2-isopropenylnaphthalene, and 1-vinylimidazole; allylbenzene; and triallyl cyanurate.

The acrylate compound may be a monofunctional acrylate compound, a difunctional acrylate compound, or a polyfunctional acrylate compound having a functionality of 3 or higher, for example.

Examples of monofunctional acrylate compounds include acrylic acid, alkyl acrylates such as methyl acrylate, ethyl acrylate, n-propyl acrylate, isopropyl acrylate, n-butyl acrylate, isobutyl acrylate, tert-butyl acrylate, n-pentyl acrylate, isopentyl acrylate, tert-pentyl acrylate, neopentyl acrylate, hexyl acrylate, octyl acrylate, decyl acrylate, and stearyl acrylate, benzyl acrylate, alkylphenol acrylate (butylphenol, octylphenol, nonylphenol, dodecylphenol, etc.), acrylate of ethylene oxide adduct, isobornyl acrylate, cyclohexyl acrylate, tricyclodecane monomethylol acrylate, 2-hydroxyethyl acrylate, 2-hydroxypropyl acrylate, 3-hydroxypropyl acrylate, 2-hydroxybutyl acrylate, 4-hydroxybutyl acrylate, hydroxypentyl acrylate, 2-hydroxy-3-phenoxypropyl acrylate, 2-hydroxy-3-butoxypropyl acrylate, 2-hydroxy-3-methoxypropyl acrylate, diethylene glycol monoacrylate, diethylene glycol monoethyl ether acrylate, triethylene glycol monoacrylate, triethylene glycol monoethyl ether acrylate, tetraethylene glycol monoacrylate, tetraethylene glycol monoethyl ether acrylate, polyethylene glycol monoacrylate, polyethylene glycol monoethyl ether acrylate, dipropylene glycol monoacrylate, polypropylene glycol monoacrylate, glycerin monoacrylate, acryloyloxyethyl phthalate, 2-acryloyloxyethyl-2-hydroxyethyl phthalate, 2-acryloyloxypropyl phthalate, β-carboxyethyl acrylate, acrylic acid dimer, ω-carboxy-polycaprolactone monoacrylate, dimethylaminoethyl acrylate, diethylaminoethyl acrylate, N-vinylpyrrolidone, N-vinylformamide, acryloylmorpholine, phenoxy ethylene glycol acrylate, phenoxy diethylene glycol acrylate, phenoxy polyethylene glycol acrylate, nonylphenoxy polyethylene glycol acrylate, 2-ethylhexylpolyethylene glycol acrylate, ethoxylated o-phenylphenol acrylate, 2-acryloyloxyethyl succinate, methoxy polyethylene glycol acrylate, and N-acryloyloxyethylhexahydrophthalimide.

Examples of difunctional acrylate compounds include ethylene glycol diacrylate, diethylene glycol diacrylate, triethylene glycol diacrylate, tetraethylene glycol diacrylate, polyethylene glycol diacrylate, propylene glycol diacrylate, dipropylene glycol diacrylate, tripropylene glycol diacrylate, polypropylene glycol diacrylate, butylene glycol diacrylate, pentyl glycol diacrylate, neopentyl glycol diacrylate, hydroxypivalyl hydroxypivalate diacrylate, hydroxypivalyl hydroxypivalate dicaprolactonate diacrylate, 1,6-hexanediol diacrylate, 1,2-hexanediol diacrylate, 1,5-hexanediol diacrylate, 2,5-hexanediol diacrylate, 1,7-heptanediol diacrylate, 1,8-octanediol diacrylate, 1,2-octanediol diacrylate, 1,9-nonanediol diacrylate, 1,2-decanediol diacrylate, 1,10-decanediol diacrylate, 1,2-decanediol diacrylate, 1,12-dodecanediol diacrylate, 1,2-dodecanediol diacrylate, 1,14-tetradecanediol diacrylate, 1,2-tetradecanediol diacrylate, 1,16-hexadecanediol diacrylate, 1,2-hexadecanediol diacrylate, 2-methyl-2,4-pentanediol diacrylate, 3-methyl-1,5-pentanediol diacrylate, 2-methyl-2-propyl-1,3-propanediol diacrylate, 2,4-dimethyl-2,4-pentanediol diacrylate, 2,2-diethyl-1,3-propanediol diacrylate, 2,2,4-trimethyl-1,3-pentanediol diacrylate, dimethylol octane diacrylate, 2-ethyl-1,3-hexanediol diacrylate, 2,5-dimethyl-2,5-hexanediol diacrylate, 2-methyl-1,8-octanediol diacrylate, 2-butyl-2-ethyl-1,3-propanediol diacrylate, 2,4-diethyl-1,5-pentanediol diacrylate, 1,2-hexanediol diacrylate, 1,5-hexanediol diacrylate, 2,5-hexanediol diacrylate, 1,7-heptanediol diacrylate, 1,8-octanediol diacrylate, 1,2-octanediol diacrylate, 1,9-nonanediol diacrylate, 1,2-decanediol diacrylate, 1,10-decanediol diacrylate, 1,2-decanediol diacrylate, 1,12-dodecanediol diacrylate, 1,2-dodecanediol diacrylate, 1,14-tetradecanediol diacrylate, 1,2-tetradecanediol diacrylate, 1,16-hexadecanediol diacrylate, 1,2-hexadecanediol diacrylate, 2-methyl-2,4-pentanediol diacrylate, 3-methyl-1,5-pentanediol diacrylate, 2-methyl-2-propyl-1,3-propanediol diacrylate, 2,4-dimethyl-2,4-pentanediol diacrylate, 2,2-diethyl-1,3-propanediol diacrylate, 2,2,4-trimethyl-1,3-pentanediol diacrylate, dimethylol octane diacrylate, 2-ethyl-1,3-hexanediol diacrylate, 2,5-dimethyl-2,5-hexanediol diacrylate, 2-butyl-2-ethyl-1,3-propanediol diacrylate, 2,4-diethyl-1,5-pentanediol diacrylate, tricyclodecane dimethylol diacrylate, tricyclodecane dimethylol dicaprolactonate diacrylate, bisphenol A tetraethylene oxide adduct diacrylate, bisphenol F tetraethylene oxide adduct diacrylate, bisphenol S tetraethylene oxide adduct diacrylate, hydrogenated bisphenol A tetraethylene oxide adduct diacrylate, hydrogenated bisphenol F tetraethylene oxide adduct diacrylate, hydrogenated bisphenol A diacrylate, hydrogenated bisphenol F diacrylate, bisphenol A tetraethylene oxide adduct dicaprolactonate diacrylate, and bisphenol F tetraethylene oxide adduct dicaprolactonate diacrylate.

Examples of polyfunctional acrylate compounds include glycerin triacrylate, trimethylolpropane triacrylate, trimethylolpropane tricaprolactonate triacrylate, trimethylolethane triacrylate, trimethylolhexane triacrylate, trimethyloloctane triacrylate, pentaerythritol triacrylate, pentaerythritol tetraacrylate, pentaerythritol tetracaprolactonate tetraacrylate, diglycerin tetraacrylate, di(trimethylolpropane) tetraacrylate, di(trimethylolpropane) tetracaprolactonate tetraacrylate, di(trimethylolethane) tetraacrylate, di(trimethylolbutane) tetraacrylate, di(trimethylolhexane) tetraacrylate, di(trimethyloloctane) tetraacrylate, dipentaerythritol pentaacrylate, dipentaerythritol hexaacrylate, tripentaerythritol hexaacrylate, tripentaerythritol heptaacrylate, tripentaerythritol octaacrylate, and tripentaerythritol polyalkylene oxide heptaacrylate.

Other examples include polyfunctional acrylates such as urethane acrylate and polyester acrylate.

The methacrylate compound may be a monofunctional methacrylate compound, a difunctional methacrylate compound, or a polyfunctional methacrylate compound having a functionality of 3 or higher, for example.

Examples of monofunctional methacrylate compounds include methacrylic acid, alkyl methacrylates such as methyl methacrylate, ethyl methacrylate, n-propyl methacrylate, isopropyl methacrylate, n-butyl methacrylate, isobutyl methacrylate, tert-butyl methacrylate, n-pentyl methacrylate, isopentyl methacrylate, tert-pentyl methacrylate, neopentyl methacrylate, hexyl methacrylate, octyl methacrylate, dodecyl methacrylate, and stearyl methacrylate, benzyl methacrylate, alkylphenol methacrylate (butylphenol, octylphenol, nonylphenol, dodecylphenol, etc.), methacrylate of ethylene oxide adduct, isobornyl methacrylate, cyclohexyl methacrylate, tricyclodecane monomethylol methacrylate, 2-hydroxyethyl methacrylate, 2-hydroxypropyl methacrylate, 3-hydroxypropyl methacrylate, 2-hydroxybutyl methacrylate, 4-hydroxybutyl methacrylate, hydroxypentyl methacrylate, 2-hydroxy-3-phenoxypropyl methacrylate, 2-hydroxy-3-butoxypropyl methacrylate, 2-hydroxy-3-methoxypropyl methacrylate, diethylene glycol monomethacrylate, diethylene glycol monoethyl ether methacrylate, triethylene glycol monomethacrylate, triethylene glycol monoethyl ether methacrylate, tetraethylene glycol monomethacrylate, tetraethylene glycol monoethyl ether methacrylate, polyethylene glycol monomethacrylate, polyethylene glycol monoethyl ether methacrylate, dipropylene glycol monomethacrylate, dipropylene glycol monoethyl ether methacrylate, polypropylene glycol monomethacrylate, polypropylene glycol monoethyl ether methacrylate, glycerin monomethacrylate, methacryloyloxyethyl phthalate, 2-methacryloyloxyethyl-2-hydroxyethyl phthalate, 2-methacryloyloxypropyl phthalate, β-carboxyethyl methacrylate, methacrylic acid dimer, ω-carboxy-polycaprolactone monomethacrylate, dimethylaminoethyl methacrylate, diethylaminoethyl methacrylate, N-vinylpyrrolidone, N-vinylformamide, methacryloylmorpholine, phenoxy ethylene glycol methacrylate, phenoxy diethylene glycol methacrylate, phenoxy polyethylene glycol methacrylate, nonylphenoxy polyethylene glycol methacrylate, 2-ethylhexyl polyethylene glycol methacrylate, ethoxylated o-phenylphenol methacrylate, 2-methacryloyloxyethyl succinate, methoxy polyethylene glycol methacrylate, and N-methacryloyloxyethylhexahydrophthalimide.

Examples of difunctional methacrylate compounds include ethylene glycol dimethacrylate, diethylene glycol dimethacrylate, triethylene glycol dimethacrylate, tetraethylene glycol dimethacrylate, polyethylene glycol dimethacrylate, propylene glycol dimethacrylate, dipropylene glycol dimethacrylate, tripropylene glycol dimethacrylate, polypropylene glycol dimethacrylate, butylene glycol dimethacrylate, pentyl glycol dimethacrylate, neopentyl glycol dimethacrylate, hydroxypivalyl hydroxypivalate dimethacrylate, hydroxypivalyl hydroxypivalate dicaprolactonate dimethacrylate, 1,6-hexanediol dimethacrylate, 1,2-hexanediol dimethacrylate, 1,5-hexanediol dimethacrylate, 2,5-hexanediol dimethacrylate, 1,7-heptanediol dimethacrylate, 1,8-octanediol dimethacrylate, 1,2-octanediol dimethacrylate, 1,9-nonanediol dimethacrylate, 1,2-decanediol dimethacrylate, 1,10-decanediol dimethacrylate, 1,2-decanediol dimethacrylate, 1,12-dodecanediol dimethacrylate, 1,2-dodecanediol dimethacrylate, 1,14-tetradecanediol dimethacrylate, 1,2-tetradecanediol dimethacrylate, 1,16-hexadecanediol dimethacrylate, 1,2-hexadecanediol dimethacrylate, 2-methyl-2,4-pentanediol dimethacrylate, 3-methyl-1,5-pentanediol dimethacrylate, 2-methyl-2-propyl-1,3-propanediol dimethacrylate, 2,4-dimethyl-2,4-pentanediol dimethacrylate, 2,2-diethyl-1,3-propanediol dimethacrylate, 2,2,4-trimethyl-1,3-pentanediol dimethacrylate, dimethylol octane dimethacrylate, 2-ethyl-1,3-hexanediol dimethacrylate, 2,5-dimethyl-2,5-hexanediol dimethacrylate, 2-methyl-1,8-octanediol dimethacrylate, 2-butyl-2-ethyl-1,3-propanediol dimethacrylate, 2,4-diethyl-1,5-pentanediol dimethacrylate, 1,2-hexanediol dimethacrylate, 1,5-hexanediol dimethacrylate, 2,5-hexanediol dimethacrylate, 1,7-heptanediol dimethacrylate, 1,8-octanediol dimethacrylate, 1,2-octanediol dimethacrylate, 1,9-nonanediol dimethacrylate, 1,2-decanediol dimethacrylate, 1,10-decanediol dimethacrylate, 1,2-decanediol dimethacrylate, 1,12-dodecanediol dimethacrylate, 1,2-dodecanediol dimethacrylate, 1,14-tetradecanediol dimethacrylate, 1,2-tetradecanediol dimethacrylate, 1,16-hexadecanediol dimethacrylate, 1,2-hexadecanediol dimethacrylate, 2-methyl-2,4-pentanediol dimethacrylate, 3-methyl-1,5-pentanediol dimethacrylate, 2-methyl-2-propyl-1,3-propanediol dimethacrylate, 2,4-dimethyl-2,4-pentanediol dimethacrylate, 2,2-diethyl-1,3-propanediol dimethacrylate, 2,2,4-trimethyl-1,3-pentanediol dimethacrylate, dimethylol octane dimethacrylate, 2-ethyl-1,3-hexanediol dimethacrylate, 2,5-dimethyl-2,5-hexanediol dimethacrylate, 2-butyl-2-ethyl-1,3-propanediol dimethacrylate, 2,4-diethyl-1,5-pentanediol dimethacrylate, tricyclodecane dimethylol dimethacrylate, tricyclodecane dimethylol dicaprolactonate dimethacrylate, bisphenol A tetraethylene oxide adduct dimethacrylate, bisphenol F tetraethylene oxide adduct dimethacrylate, bisphenol S tetraethylene oxide adduct dimethacrylate, hydrogenated bisphenol A tetraethylene oxide adduct dimethacrylate, hydrogenated bisphenol F tetraethylene oxide adduct dimethacrylate, hydrogenated bisphenol A dimethacrylate, hydrogenated bisphenol F dimethacrylate, bisphenol A tetraethylene oxide adduct dicaprolactonate dimethacrylate, and bisphenol F tetraethylene oxide adduct dicaprolactonate dimethacrylate.

Examples of polyfunctional methacrylate compounds include glycerin trimethacrylate, trimethylolpropane trimethacrylate, trimethylolpropane tricaprolactonate trimethacrylate, trimethylolethane trimethacrylate, trimethylolhexane trimethacrylate, trimethyloloctane trimethacrylate, pentaerythritol trimethacrylate, pentaerythritol tetramethacrylate, pentaerythritol tetracaprolactonate tetramethacrylate, diglycerin tetramethacrylate, di(trimethylolpropane) tetramethacrylate, di(trimethylolpropane) tetracaprolactonate tetramethacrylate, di(trimethylolethane) tetramethacrylate, di(trimethylolbutane) tetramethacrylate, di(trimethylolhexane) tetramethacrylate, di(trimethyloloctane) tetramethacrylate, dipentaerythritol pentamethacrylate, dipentaerythritol hexamethacrylate, tripentaerythritol hexamethacrylate, tripentaerythritol heptamethacrylate, tripentaerythritol octamethacrylate, and tripentaerythritol polyalkylene oxide heptamethacrylate. Other examples include methacrylates such as urethane methacrylate and polyester methacrylate.

Examples of isocyanurate compounds that can be used as the cross-linker include polyfunctional (meth)acryloyl group-containing isocyanurates such as tri(acryloyloxyethyl) isocyanurate, tri(methacryloyloxyethyl) isocyanurate, alkylene oxide adduct of tri(acryloyloxyethyl) isocyanurate, and alkylene oxide adduct of tri(methacryloyloxyethyl) isocyanurate; and polyfunctional allyl group-containing isocyanurates such as triallyl isocyanurate.

Specific examples of cross-linkers that can suitably be used include a mixture of ethylene oxide-modified isocyanurate diacrylate and ethylene oxide-modified isocyanurate triacrylate (produced by Toagosei Co., Ltd.; product name: ARONIX® M-315 (ARONIX is a registered trademark in Japan, other countries, or both)), trimethylolpropane triacrylate (produced by Toagosei Co., Ltd.; product name: ARONIX® M-309), a mixture of dipentaerythritol pentaacrylate and dipentaerythritol hexaacrylate (produced by Toagosei Co., Ltd.; product name: ARONIX® M-403), polyethylene glycol diacrylate (produced by Toagosei Co., Ltd.; product name: ARONIX® M-240), N-acryloyloxyethylhexahydrophthalimide (produced by Toagosei Co., Ltd.; product name: ARONIX® M-140), nonylphenoxy polyethylene glycol acrylate (produced by Toagosei Co., Ltd.; product name: ARONIX® M-113), triethylene glycol divinyl ether (produced by Nippon Carbide Industries Co., Ltd.; product name: TEGDVE), triallyl isocyanurate (produced by Mitsubishi Chemical Corporation; product name: TAIC), phenoxy ethylene glycol methacrylate (produced by Shin-Nakamura Chemical Co., Ltd.; product name: NK ESTER PHE-1G), phenoxy polyethylene glycol acrylate (produced by Shin-Nakamura Chemical Co., Ltd.; product name: NK ESTER AMP20GY), ethoxylated o-phenylphenol acrylate (produced by Shin-Nakamura Chemical Co., Ltd.; product name: NK ESTER A-LEN-10), 2-acryloyloxyethyl succinate (produced by Shin-Nakamura Chemical Co., Ltd.; product name: NK ESTER A-SA), and 2-methacryloyloxyethyl succinate (produced by Shin-Nakamura Chemical Co., Ltd.; product name: NK ESTER SA).

Note that one cross-linker can be used individually, or a plurality of cross-linkers can be used in combination.

The amount of the cross-linker when the subsequently described polymer is taken to be 100 parts by mass is preferably 1 part by mass or more, more preferably 2 parts by mass or more, even more preferably 3 parts by mass or more, particularly preferably 4 parts by mass or more, and most preferably 5 parts by mass or more, and is preferably 60 parts by mass or less, more preferably 50 parts by mass or less, even more preferably 40 parts by mass or less, particularly preferably 35 parts by mass or less, and most preferably 30 parts by mass or less. When the amount of the cross-linker is within any of the ranges set forth above, an even better exposure margin widening effect and pattern clarifying effect can be obtained. Moreover, when the amount of the cross-linker is within any of the ranges set forth above, the resolution of an obtained resist pattern can be increased.

Note that the amount of the cross-linker can be further optimized in accordance with the functionality of the cross-linker. For example, in a case in which the cross-linker is monofunctional, the amount of the cross-linker is preferably not less than 6 parts by mass and not more than 60 parts by mass when the polymer is taken to be 100 parts by mass. In a case in which the cross-linker is difunctional, the amount of the cross-linker is preferably not less than 5 parts by mass and not more than 50 parts by mass when the polymer is taken to be 100 parts by mass. In a case in which the cross-linker is trifunctional, the amount of the cross-linker is preferably not less than 4 parts by mass and not more than 40 parts by mass when the polymer is taken to be 100 parts by mass. Moreover, in a case in which the cross-linker is pentafunctional, for example, the amount of the cross-linker is preferably not less than 3 parts by mass and not more than 30 parts by mass when the polymer is taken to be 100 parts by mass. When the amount of a cross-linker having a specific functionality is within the range set forth above, an even better exposure margin widening effect and pattern clarifying effect can be obtained. Moreover, when the amount of a cross-linker having a specific functionality is within the range set forth above, the resolution of an obtained resist pattern can be increased.

### <Polymer>

No specific limitations are placed on the polymer that is used in the presently disclosed method of forming a resist pattern. For example, the polymer may be a main chain scission-type polymer or may be a chemical amplification-type polymer. Note that one main chain scission-type polymer can be used individually, or a plurality of main chain scission-type polymers can be used in combination. Moreover, one chemical amplification-type polymer can be used individually, or a plurality of chemical amplification-type polymers can be used in combination. In particular, it is preferable that the polymer is a polymer that can be used well as a main chain scission-type positive resist that undergoes main chain scission to lower molecular weight upon irradiation with exposure light such as ionizing radiation (electron beam, etc.) or non-ionizing radiation having a wavelength of 300 nm or less. This is because an even better exposure margin widening effect and pattern clarifying effect can be obtained when the polymer is a main chain scission-type polymer. Examples of such polymers that can be used include, but are not specifically limited to, those described in JP-H8-3636B2, JP2020-134683A, WO2019/150966A1, and WO2020/066806A1.

In particular, from a viewpoint of obtaining an even better exposure margin widening effect and pattern clarifying effect, it is preferable that the polymer is a copolymer including: a monomer unit (A) represented by general formula (I), shown below,

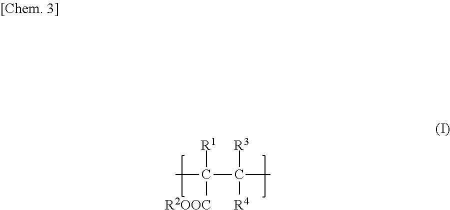

(in formula (I), R¹ is a halogen atom or a halogen atom-substituted alkyl group, R² is a hydrogen atom or an organic group including not fewer than 0 and not more than 11 fluorine atoms, and R³ and R⁴ are each a hydrogen atom, a halogen atom, an unsubstituted alkyl group, or a halogen atom-substituted alkyl group and may be the same as or different from each other); and a monomer unit (B) represented by general formula (II), shown below,

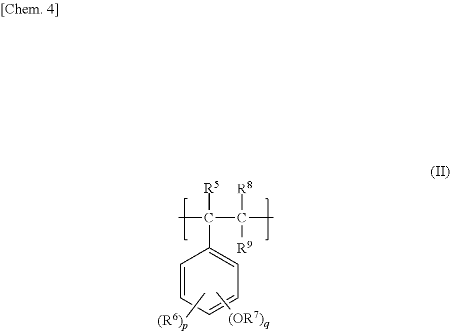

(in formula (II), R⁵, R⁶, R⁸, and R⁹ are each a hydrogen atom, a halogen atom, an unsubstituted alkyl group, or a halogen atom-substituted alkyl group and may be the same as or different from one another, R⁷ is a hydrogen atom, an unsubstituted alkyl group, or a halogen atom-substituted alkyl group, p and q are each an integer of not less than 0 and not more than 5, and p+q=5).

Note that although the above-described copolymer may include any monomer units other than the monomer unit (A) and the monomer unit (B), the proportion constituted by the monomer unit (A) and the monomer unit (B) among all monomer units of the copolymer is, in total, preferably 90 mol % or more, more preferably substantially 100 mol %, and even more preferably 100 mol % (i.e., the copolymer even more preferably only includes the monomer unit (A) and the monomer unit (B)).

Moreover, although the above-described copolymer may be a random polymer, a block polymer, an alternating polymer (ABAB . . . ), or the like, for example, so long as it includes the monomer unit (A) and the monomer unit (B), it is preferable that it is a copolymer comprising 90 mass % or more (upper limit 100 mass %) of an alternating polymer.

The above-described copolymer undergoes main chain scission to lower molecular weight upon irradiation with exposure light as a result of including the specific monomer unit (A) and monomer unit (B).

### —Monomer Unit (A)—

The monomer unit (A) is a structural unit that is derived from a monomer (a) represented by the following general formula (III).

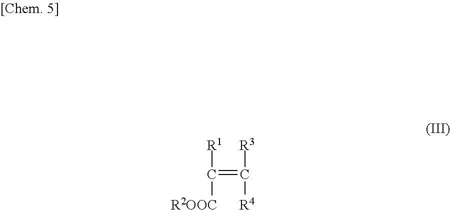

(In formula (III), R¹ to R⁴ are the same as in formula (I).)

The proportion constituted by the monomer unit (A) among all monomer units of the copolymer is not specifically limited and can be set as not less than 30 mol % and not more than 70 mol %, for example.

The halogen atom that can constitute R¹, R³, and R⁴ in formula (I) and formula (III) may be a chlorine atom, a fluorine atom, a bromine atom, or an iodine atom without any specific limitations. The halogen atom-substituted alkyl group that can constitute R¹, R³, and R⁴ in formula (I) and formula (III) may be a group having a structure resulting from a portion of or all of the hydrogen atoms in an alkyl group being replaced by any of the above-described halogen atoms without any specific limitations.

The unsubstituted alkyl group that can constitute R³ and R⁴ in formula (I) and formula (III) may be an unsubstituted alkyl group having a carbon number of not less than 1 and not more than 10 without any specific limitations. In particular, the unsubstituted alkyl group that can constitute R³ and R⁴ is preferably a methyl group or an ethyl group.

From a viewpoint of improving main chain scission properties of the copolymer upon irradiation with exposure light and increasing efficiency of resist pattern formation, R¹ in formula (I) and formula (III) is preferably a chlorine atom, a fluorine atom, or a fluorine atom-substituted alkyl group having a carbon number of not less than 1 and not more than 5, more preferably a chlorine atom, a fluorine atom, or a perfluoromethyl group, even more preferably a chlorine atom or a fluorine atom, and particularly preferably a chlorine atom. Note that a monomer (a) for which R¹ in formula (III) is a chlorine atom has excellent polymerizability, whereas a copolymer including a monomer unit (A) for which R¹ in formula (I) is a chlorine atom is also excellent in terms of ease of production.

Moreover, from a viewpoint of improving main chain scission properties of the polymer upon irradiation with exposure light and increasing efficiency of resist pattern formation, R³ and R⁴ in formula (I) and formula (III) are each preferably a hydrogen atom or an unsubstituted alkyl group, more preferably a hydrogen atom or an unsubstituted alkyl group having a carbon number of not less than 1 and not more than 5, and even more preferably a hydrogen atom.

Furthermore, R² in formula (I) and formula (III) is preferably a hydrogen atom or an organic group including 0 or more fluorine atoms. On the other hand, R² in formula (I) and formula (III) is preferably an organic group including 11 or fewer fluorine atoms from a viewpoint of further improving the clarity of an obtained resist pattern. Note that in a case in which R² is an organic group, the carbon number of R² is normally not less than 1 and not more than 12.

Specifically, R² in formula (I) and formula (III) is preferably an optionally substituted alkyl group, an optionally substituted alkoxyalkyl group, an optionally substituted alkoxyalkenyl group, or a group represented by a formula L-Ar (in the formula, L is a single bond or a divalent linking group, and Ar is an optionally substituted aromatic ring group). The substituent may be a halogen atom such as a chlorine atom, a fluorine atom, a bromine atom, or an iodine atom without any specific limitations.

R² in formula (I) and formula (III) is more preferably an alkyl group, an alkoxyalkyl group, an alkoxyalkenyl group, a fluoroalkyl group, a fluoroalkoxyalkyl group, a fluoroalkoxyalkenyl group, or a group represented by L-Ar.

The alkyl group constituting R² is preferably a methyl group, an ethyl group, a propyl group, or a butyl group.

The alkoxyalkyl group constituting R² is preferably a methoxymethyl group, an ethoxymethyl group, or an ethoxyethyl group.

The alkoxyalkenyl group constituting R² is preferably a methoxyvinyl group or an ethoxyvinyl group.

The fluoroalkyl group constituting R² is preferably a monofluoromethyl group (number of fluorine atoms: 1; carbon number: 1), a monofluoroethyl group (number of fluorine atoms: 1; carbon number: 2), a 2,2-difluoroethyl group (number of fluorine atoms: 2; carbon number: 2), a 2,2,2-trifluoromethyl group (number of fluorine atoms: 3; carbon number: 1), a 2,2,2-trifluoroethyl group (number of fluorine atoms: 3; carbon number: 2), a 2,2,3,3,3-pentafluoropropyl group (number of fluorine atoms: 5; carbon number 3), a 3,3,4,4,4-pentafluorobutyl group (number of fluorine atoms: 5; carbon number: 4), a 2-(perfluorobutyl)ethyl group (number of fluorine atoms: 9; carbon number: 6), a 1H,1H,3H-tetrafluoropropyl group (number of fluorine atoms: 4; carbon number: 3), a 1H,1H,5H-octafluoropentyl group (number of fluorine atoms: 8; carbon number: 5), a 1H-1-(trifluoromethyl)trifluoroethyl group (number of fluorine atoms: 6; carbon number: 3), a 1H,1H,3H-hexafluorobutyl group (number of fluorine atoms: 6; carbon number: 4), a 2,2,3,3,4,4,4-heptafluorobutyl group (number of fluorine atoms: 7; carbon number: 4), or a 1,2,2,2-tetrafluoro-1-(trifluoromethyl)ethyl group (number of fluorine atoms: 7; carbon number: 3), and more preferably a 2,2,3,3,3-pentafluoropropyl group, a 1H-1-(trifluoromethyl)trifluoroethyl group, a 1H,1H,3H-hexafluorobutyl group, a 2,2,3,3,4,4,4-heptafluorobutyl group, or a 1,2,2,2-tetrafluoro-1-(trifluoromethyl)ethyl group.

The fluoroalkoxyalkyl group constituting R² is preferably a pentafluoromethoxymethyl group (number of fluorine atoms: 5; carbon number: 2), a pentafluoroethoxymethyl group (number of fluorine atoms: 5; carbon number: 3), or a pentafluoroethoxyethyl group (number of fluorine atoms: 5; carbon number: 4), for example.

The fluoroalkoxyalkenyl group constituting R² is preferably a pentafluoroethoxyvinyl group (number of fluorine atoms: 5; carbon number: 4), for example.

The divalent linking group that can constitute L in the group represented by the formula L-Ar may be an optionally substituted alkylene group, an optionally substituted alkenylene group, or the like, for example, without any specific limitations.

The alkylene group of the optionally substituted alkylene group may be a chain alkylene group such as a methylene group, an ethylene group, a propylene group, an n-butylene group, or an isobutylene group or a cyclic alkylene group such as a 1,4-cyclohexylene group, for example, without any specific limitations. In particular, the alkylene group is preferably a chain alkylene group having a carbon number of 1 to 6 such as a methylene group, an ethylene group, a propylene group, an n-butylene group, or an isobutylene group, more preferably a linear alkylene group having a carbon number of 1 to 6 such as a methylene group, an ethylene group, a propylene group, or a n-butylene group, and even more preferably a linear alkylene group having a carbon number of 1 to 3 such as a methylene group, an ethylene group, or a propylene group.

The alkenylene group of the optionally substituted alkenylene group may be a chain alkenylene group such as an ethenylene group, a 2-propenylene group, a 2-butenylene group, or a 3-butenylene group or a cyclic alkenylene group such as a cyclohexenylene group, for example, without any specific limitations. In particular, the alkenylene group is preferably a linear alkenylene group having a carbon number of 2 to 6 such as an ethenylene group, a 2-propenylene group, a 2-butenylene group, or a 3-butenylene group.

Of the examples described above, the divalent linking group is preferably an optionally substituted alkylene group from a viewpoint of improving sensitivity to exposure light and heat resistance, and is more preferably an optionally substituted chain alkylene group having a carbon number of 1 to 6, even more preferably an optionally substituted linear alkylene group having a carbon number of 1 to 6, and particularly preferably an optionally substituted linear alkylene group having a carbon number of 1 to 3.

Moreover, from a viewpoint of improving sensitivity to exposure light, the divalent linking group that can constitute L preferably includes one or more electron withdrawing groups. In particular, in a case in which the divalent linking group is an alkylene group that includes an electron withdrawing group as a substituent or an alkenylene group that includes an electron withdrawing group as a substituent, the electron withdrawing group is preferably bonded to a carbon that is bonded to an O adjacent to a carbonyl carbon in formula (I) and formula (III).

Note that one or more selected from the group consisting of a fluorine atom, a fluoroalkyl group, a cyano group, and a nitro group may, for example, serve as an electron withdrawing group that can improve sensitivity to exposure light without any specific limitations. The fluoroalkyl group may be a fluoroalkyl group having a carbon number of 1 to 5, for example, without any specific limitations. In particular, the fluoroalkyl group is preferably a perfluoroalkyl group having a carbon number of 1 to 5, and more preferably a trifluoromethyl group.

Furthermore, from a viewpoint of improving sensitivity to exposure light and heat resistance, L is preferably a methylene group, a cyanomethylene group, a trifluoromethylmethylene group, or a bis(trifluoromethyl)methylene group, and more preferably a bis(trifluoromethyl)methylene group.

Ar in the group represented by the formula L-Ar may be an optionally substituted aromatic hydrocarbon ring group or an optionally substituted heterocyclic group.

The aromatic hydrocarbon ring group may be a benzene ring group, a biphenyl ring group, a naphthalene ring group, an azulene ring group, an anthracene ring group, a phenanthrene ring group, a pyrene ring group, a chrysene ring group, a naphthacene ring group, a triphenylene ring group, an o-terphenyl ring group, an m-terphenyl ring group, a p-terphenyl ring group, an acenaphthene ring group, a coronene ring group, a fluorene ring group, a fluoranthene ring group, a pentacene ring group, a perylene ring group, a pentaphene ring group, a picene ring group, a pyranthrene ring group, or the like, for example, without any specific limitations.

The aromatic heterocyclic group may be a furan ring group, a thiophene ring group, a pyridine ring group, a pyridazine ring group, a pyrimidine ring group, a pyrazine ring group, a triazine ring group, an oxadiazole ring group, a triazole ring group, an imidazole ring group, a pyrazole ring group, a thiazole ring group, an indole ring group, a benzimidazole ring group, a benzothiazole ring group, a benzoxazole ring group, a quinoxaline ring group, a quinazoline ring group, a phthalazine ring group, a benzofuran ring group, a dibenzofuran ring group, a benzothiophene ring group, a dibenzothiophene ring group, a carbazole ring group, or the like, for example, without any specific limitations.

Examples of possible substituents of Ar include an alkyl group, a fluorine atom, and a fluoroalkyl group without any specific limitations. Examples of alkyl groups that are possible substituents of Ar include chain alkyl groups having a carbon number of 1 to 6 such as a methyl group, an ethyl group, a propyl group, an n-butyl group, and an isobutyl group. Examples of fluoroalkyl groups that are possible substituents of Ar include fluoroalkyl groups having a carbon number of 1 to 5 such as a trifluoromethyl group, a trifluoroethyl group, and a pentafluoropropyl group.

Of these examples, an optionally substituted aromatic hydrocarbon ring group is preferable as Ar from a viewpoint of improving sensitivity to exposure light and heat resistance, with an unsubstituted aromatic hydrocarbon ring group being more preferable, and a benzene ring group (phenyl group) being even more preferable.

The monomer (a) represented by formula (III) described above that can form the monomer unit (A) represented by formula (I) described above may be an α-chloroacrylic acid alkyl ester such as methyl α-chloroacrylate, ethyl α-chloroacrylate, propyl α-chloroacrylate, or butyl α-chloroacrylate; an α-fluoroacrylic acid alkyl ester such as methyl α-fluoroacrylate, ethyl α-fluoroacrylate, propyl α-fluoroacrylate, or butyl α-fluoroacrylate; an α-chloroacrylic acid alkoxyalkyl ester such as methoxymethyl α-chloroacrylate, ethoxymethyl α-chloroacrylate, or ethoxyethyl α-chloroacrylate; an α-fluoroacrylic acid alkoxyalkyl ester such as methoxymethyl α-fluoroacrylate, ethoxymethyl α-fluoroacrylate, or ethoxyethyl α-fluoroacrylate; an α-chloroacrylic acid alkoxyalkenyl ester such as methoxyvinyl α-chloroacrylate or ethoxyvinyl α-chloroacrylate; an α-fluoroacrylic acid alkoxyalkenyl ester such as methoxyvinyl α-fluoroacrylate or ethoxyvinyl α-fluoroacrylate; an α-chloroacrylic acid fluoroalkyl ester such as monofluoromethyl α-chloroacrylate, monofluoroethyl α-chloroacrylate, 2,2-difluoroethyl α-chloroacrylate, 2,2,2-trifluoroethyl α-chloroacrylate, 2,2,3,3,3-pentafluoropropyl α-chloroacrylate, 3,3,4,4,4-pentafluorobutyl α-chloroacrylate, 2-(perfluorobutyl)ethyl α-chloroacrylate, 1H,1H,3H-tetrafluoropropyl α-chloroacrylate, 1H,1H,5H-octafluoropentyl α-chloroacrylate, 1H-1-(trifluoromethyl)trifluoroethyl α-chloroacrylate, 1H,1H,3H-hexafluorobutyl α-chloroacrylate, 2,2,3,3,4,4,4-heptafluorobutyl α-chloroacrylate, or 1,2,2,2-tetrafluoro-1-(trifluoromethyl)ethyl α-chloroacrylate; an α-fluoroacrylic acid fluoroalkyl ester such as 2,2,2-trifluoroethyl α-fluoroacrylate, 2,2,3,3,3-pentafluoropropyl α-fluoroacrylate, 3,3,4,4,4-pentafluorobutyl α-fluoroacrylate, 2-(perfluorobutyl)ethyl α-fluoroacrylate, 1H,1H,3H-tetrafluoropropyl α-fluoroacrylate, 1H,1H,5H-octafluoropentyl α-fluoroacrylate, 1H-1-(trifluoromethyl)trifluoroethyl α-fluoroacrylate, 1H,1H,3H-hexafluorobutyl α-fluoroacrylate, 2,2,3,3,4,4,4-heptafluorobutyl α-fluoroacrylate, or 1,2,2,2-tetrafluoro-1-(trifluoromethyl)ethyl α-fluoroacrylate; an α-chloroacrylic acid fluoroalkoxyalkyl ester such as pentafluoroethoxymethyl α-chloroacrylate or pentafluoroethoxyethyl α-chloroacrylate; an α-fluoroacrylic acid fluoroalkoxyalkyl ester such as pentafluoroethoxymethyl α-fluoroacrylate or pentafluoroethoxyethyl α-fluoroacrylate; an α-chloroacrylic acid fluoroalkoxyalkenyl ester such as pentafluoroethoxyvinyl α-chloroacrylate; an α-fluoroacrylic acid fluoroalkoxyalkenyl ester such as pentafluoroethoxyvinyl α-fluoroacrylate; benzyl α-chloroacrylate; 1-phenyl-1-trifluoromethyl-2,2,2-trifluoroethyl α-chloroacrylate; or the like, for example, without any specific limitations.

Note that from a viewpoint of improving main chain scission properties of the copolymer upon irradiation with exposure light and increasing efficiency of resist pattern formation, the monomer unit (A) is preferably a structural unit derived from an α-chloroacrylic acid alkyl ester such as methyl α-chloroacrylate or a structural unit derived from 1-phenyl-1-trifluoromethyl-2,2,2-trifluoroethyl α-chloroacrylate.

### —Monomer Unit (B)—

The monomer unit (B) is a structural unit that is derived from a monomer (b) represented by general formula (IV), shown below.

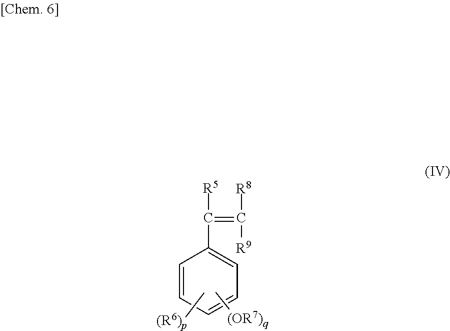

(In formula (IV), R⁵ to R⁹, p, and q are the same as in formula (II).)

The proportion constituted by the monomer unit (B) among all monomer units of the polymer is not specifically limited and can be set as not less than 30 mol % and not more than 70 mol %, for example.

The halogen atom and the halogen atom-substituted alkyl group that can constitute R⁵ to R⁹ in formula (II) and formula (IV) may be a halogen atom such as a chlorine atom, a fluorine atom, a bromine atom, or an iodine atom and a group having a structure resulting from a portion of or all of the hydrogen atoms in an alkyl group being replaced with any of the halogen atoms described above without any specific limitations.

Moreover, the unsubstituted alkyl group that can constitute R⁵ to R⁹ in formula (II) and formula (IV) may be an unsubstituted alkyl group having a carbon number of not less than 1 and not more than 5 without any specific limitations. In particular, the unsubstituted alkyl group that can constitute R⁵ to R⁹ is preferably a methyl group or an ethyl group.

Moreover, from a viewpoint of improving ease of production of the copolymer and main chain scission properties of the copolymer upon irradiation with exposure light, R⁵ in formula (II) and formula (IV) is preferably a hydrogen atom or an unsubstituted alkyl group, more preferably an unsubstituted alkyl group having a carbon number of not less than 1 and not more than 5, and even more preferably a methyl group.

Furthermore, from a viewpoint of improving ease of production of the copolymer, the plurality of R⁶ and/or R⁷ groups present in formula (II) and formula (IV) are each preferably a hydrogen atom or an unsubstituted alkyl group, more preferably a hydrogen atom or an unsubstituted alkyl group having a carbon number of not less than 1 and not more than 5, and even more preferably a hydrogen atom.

Note that from a viewpoint of improving ease of production of the copolymer, it is preferable that p is 5, q is 0, and the five R⁶ groups are each a hydrogen atom or an unsubstituted alkyl group in formula (II) and formula (IV), more preferable that the five R⁶ groups are each a hydrogen atom or an unsubstituted alkyl group having a carbon number of not less than 1 and not more than 5, and even more preferable that the five R⁶ groups are each a hydrogen atom.

Moreover, from a viewpoint of improving ease of production of the copolymer and main chain scission properties of the copolymer upon irradiation with exposure light, R⁸ and R⁹ in formula (II) and formula (IV) are each preferably a hydrogen atom or an unsubstituted alkyl group, more preferably a hydrogen atom or an unsubstituted alkyl group having a carbon number of not less than 1 and not more than 5, and even more preferably a hydrogen atom.

The monomer (b) represented by formula (IV) described above that can form the monomer unit (B) represented by formula (II) described above may be α-methylstyrene (AMS) or a derivative thereof, such as the following (b-1) to (b-11), for example, without any specific limitations.

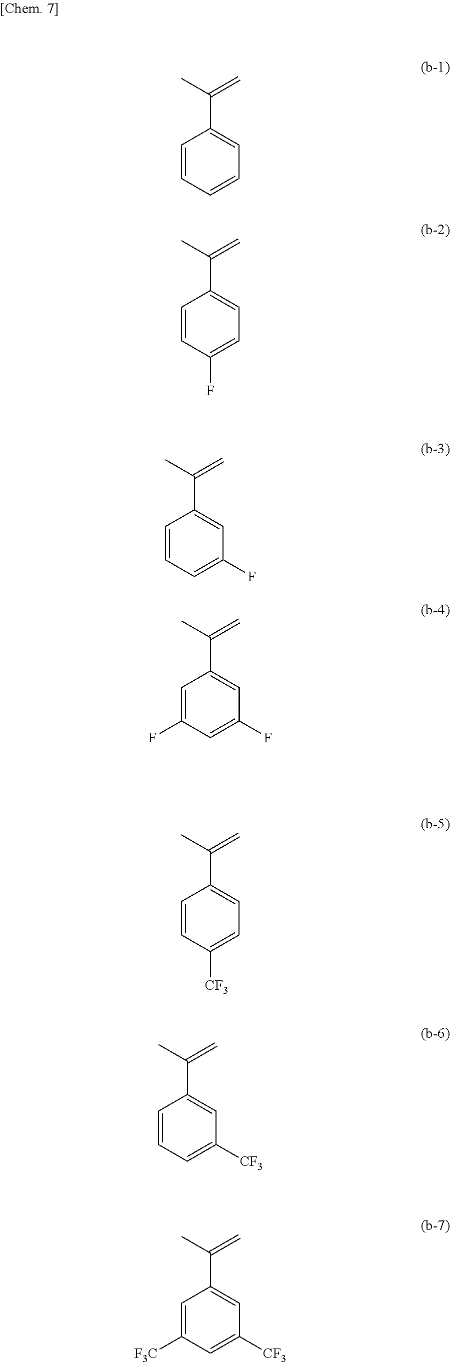

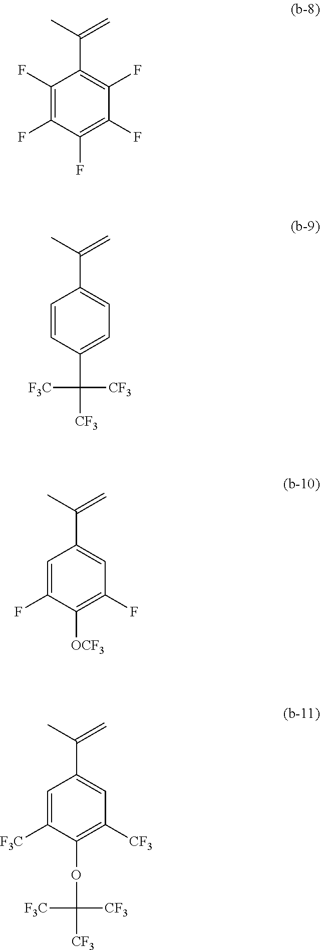

Note that from a viewpoint of improving ease of production of the copolymer, it is preferable that the monomer unit (B) does not include a fluorine atom, and more preferable that the monomer unit (B) is a structural unit derived from α-methylstyrene. In other words, it is particularly preferable that for R⁵ to R⁹, p, and q in formula (II) and formula (IV), p=5, q=0, R⁵ is a methyl group, each of the five R⁶ groups is a hydrogen atom, and R⁸ and R⁹ are each a hydrogen atom.

### —Weight-Average Molecular Weight—

The weight-average molecular weight (Mw) of the copolymer is preferably 10,000 or more, more preferably 30,000 or more, and even more preferably 40,000 or more, and is preferably 500,000 or less, and more preferably 300,000 or less. When the weight-average molecular weight (Mw) of the polymer is within a range that is not less than any of the lower limits set forth above and not more than any of the upper limits set forth above, an even better exposure margin widening effect and pattern clarifying effect can be obtained. Note that the weight-average molecular weight of the copolymer can be determined as a standard polystyrene-equivalent value by gel permeation chromatography, for example. The weight-average molecular weight of the copolymer can be measured by a method described in JP2020-134683A, for example.

### —Number-Average Molecular Weight—

The number-average molecular weight (Mn) of the copolymer is preferably 6,000 or more, more preferably 18,000 or more, and even more preferably 24,000 or more, and is preferably 300,000 or less, more preferably 250,000 or less, and even more preferably 200,000 or less. When the number-average molecular weight (Mn) of the copolymer is within a range that is not less than any of the lower limits set forth above and not more than any of the upper limits set forth above, an even better exposure margin widening effect and pattern clarifying effect can be obtained.

The number-average molecular weight (Mn) of the copolymer can be measured by the same method as the weight-average molecular weight (Mw) described above.

### —Molecular Weight Distribution—

The molecular weight distribution (Mw/Mn) of the copolymer is preferably 1.1 or more, and more preferably 1.2 or more, and is preferably 2.3 or less, and more preferably 2.0 or less. When the molecular weight distribution (Mw/Mn) of the copolymer is 1.1 or more, ease of production of the copolymer can be increased. On the other hand, when the molecular weight distribution (Mw/Mn) of the copolymer is 2.3 or less, the clarity of an obtained resist pattern can be improved.

### —Production Method—

The polymer can be produced by, for example, performing polymerization of a monomer composition containing monomer(s) and then optionally purifying the resultant polymerized product. Polymerization of the monomer composition containing monomer(s) and purification of the resultant polymerized product can be performed by methods described in JP2020-134683A, for example.

### <Solvent>

Any known solvent can be used as the solvent without any specific limitations so long as it is a solvent in which the above-described copolymer can dissolve. In particular, it is preferable that anisole, propylene glycol monomethyl ether acetate (PGMEA), cyclopentanone, cyclohexanone, hexyl acetate, or isoamyl acetate is used as the solvent from a viewpoint of improving coatability of the resist composition. Note that one solvent may be used individually, or a plurality of solvents may be used as a mixture.

### <Other Components>

The presently disclosed resist composition may optionally further contain known additives that can be compounded in resist compositions in addition to the essential components described above. Additives can be added in an appropriate amount depending on the application without any specific limitations on the amount thereof.

### <Production Method of Resist Composition>

The presently disclosed resist composition can be produced by mixing the specific cross-linker described above, the solvent, the polymer, and the optionally compounded additives without any specific limitations. A known mixing method can be adopted as the mixing method without any specific limitations. Note that a mixture obtained through mixing of the compounded materials described above can be filtered using a filtration material such as a filter as necessary.

### (Method of Forming Resist Pattern)

The presently disclosed method of forming a resist pattern includes: a step (resist film formation step) of performing resist film formation by applying a resist composition containing a cross-linker that reacts in response to ionizing radiation or non-ionizing radiation having a wavelength of 300 nm or less, a solvent, and a polymer onto a substrate to obtain a coating layer, and removing the solvent from the coating layer to form a resist film; and a step (exposure step) of performing exposure by exposing the resist film formed in the resist film formation step using ionizing radiation or non-ionizing radiation having a wavelength of 300 nm or less as exposure light and causing a cross-linking reaction to proceed through the cross-linker while forming a latent pattern. In addition, the presently disclosed method of forming a resist pattern may further include a step (development step) of developing the latent pattern obtained in the exposure step, a step (post exposure bake step) of heating the resist film between the exposure step and the development step, and/or a step (rinsing step) of washing and removing the developer after the development step. The following describes each of these steps.

### (Resist Film Formation Step)

In the resist film formation step, the specific resist composition is applied onto a workpiece, such as a substrate, that is to be processed using a resist pattern so as to obtain a coating layer (application step), and then the solvent is removed from the obtained coating layer to form a resist film (drying step).

### <Application Step>

The workpiece onto which the specific resist composition is applied in the application step is not specifically limited and may be a semiconductor substrate that is used in the production of a semiconductor device or the like; a substrate including an insulating layer and copper foil provided on the insulating layer that is used in production of a printed board or the like; or a mask blank having a light shielding layer formed on a substrate, for example. Moreover, a known method can be adopted as the application method of the specific resist composition without any specific limitations.

Furthermore, the presently disclosed resist composition set forth above can suitably be used as the specific resist composition that is applied onto the workpiece.

### <Drying Step>

No specific limitations are placed on the method by which the solvent is removed from the coating layer. Although any drying method that is typically used in resist film formation can be adopted, it is preferable that the resist composition is heated (prebaked) to form the resist film.

The temperature at which the coating layer is dried (drying temperature) is preferably 100° C. or higher, and more preferably 110° C. or higher from a viewpoint of close adherence between the workpiece and the resist film that is formed through the drying step, and is preferably 250° C. or lower, and more preferably 200° C. or lower from a viewpoint of reducing the effect of heat on the workpiece and the resist film. Moreover, the time for which the coating layer is dried (drying time) is preferably more than 10 seconds, more preferably 30 seconds or more, and even more preferably 1 minute or more from a viewpoint of implementing the drying step in a lower temperature range and sufficiently improving close adherence between the formed resist film and the workpiece, and is preferably 60 minutes or less, and more preferably 30 minutes or less from a viewpoint of reducing change of molecular weight of the polymer in the resist film between before and after the drying step.

### (Exposure Step)

In the exposure step, a specific position on the resist film that has been formed in the resist film formation step is irradiated with exposure light that is ionizing radiation or non-ionizing radiation having a wavelength of 300 nm or less so as to write a desired pattern. Irradiation with the exposure light creates a poorly soluble portion A and a highly soluble portion B in the resist film and forms a latent pattern. Moreover, in the exposure step, a cross-linking reaction is caused to proceed through the cross-linker while forming the latent pattern. In particular, in a case in which the polymer forming the resist film is a main chain scission-type polymer, the cross-linking reaction and a main chain scission reaction of the polymer proceed concurrently in the exposure step. This case is even more advantageous in terms of widening of the exposure margin and clarity of an obtained resist pattern.

The ionizing radiation is radiation having sufficient energy for ionizing atoms or molecules. In contrast, the non-ionizing radiation is radiation that does not have sufficient energy for ionizing atoms or molecules.

The ionizing radiation may be an electron beam, extreme ultraviolet light, gamma rays, X-rays, alpha rays, a heavy particle beam, a proton beam, beta rays, an ion beam, or the like, for example. In particular, the ionizing radiation is preferably an electron beam or extreme ultraviolet light, and more preferably an electron beam. Note that the wavelength of the extreme ultraviolet light is not specifically limited and can be set as not less than 1 nm and not more than 30 nm, for example, and can preferably be set as 13.5 nm.

The non-ionizing radiation having a wavelength of 300 nm or less may be far ultraviolet light (wavelength of not less than 40 nm and not more than 200 nm) other than extreme ultraviolet light, near ultraviolet light (wavelength of more than 200 nm and not more than 300 nm), or the like, for example. In particular, a KrF excimer laser beam (wavelength=248 nm) or an ArF excimer laser beam (wavelength=193 nm) is preferable.

The irradiation dose in the exposure step is not specifically limited but is normally not less than 10 mJ/cm² and not more than 3,000 mJ/cm², and, in the case of an electron beam (EB), is normally not less than 0.1 μC/cm² and not more than 1,000 μC/cm². Moreover, a known exposure tool such as an electron beam lithography tool or a laser writer can be used as the exposure tool that implements the exposure step, for example.

### (Post Exposure Bake Step)

In the presently disclosed method of forming a resist pattern, a post exposure bake step of heating the resist film after the exposure step can optionally be performed from a viewpoint of mitigating a standing wave effect due to exposure and inhibiting the formation of unevenness in a resist pattern.

The heating temperature is not specifically limited but is preferably 80° C. or higher, and more preferably 100° C. or higher from a viewpoint of sufficiently inhibiting the formation of unevenness in a resist pattern, and is preferably 160° C. or lower, and more preferably 140° C. or lower from a viewpoint of inhibiting gas evolution due to decomposition of the resist film by heat.

The time for which the resist film is heated (heating time) in the post exposure bake step is not specifically limited but is preferably 30 seconds or more, and more preferably 1 minute or more from a viewpoint of sufficiently inhibiting formation of unevenness in a resist pattern, and is preferably 20 minutes or less, and more preferably 10 minutes or less from a viewpoint of production efficiency.

The method by which the resist film is heated in the post exposure bake step is not specifically limited and may be a method in which the resist film is heated by a hot plate, a method in which the resist film is heated in an oven, or a method in which hot air is blown against the resist film, for example.

### (Development Step)

In the development step, the latent pattern of the resist film that has undergone the exposure step or the post exposure bake step is developed to form a developed film on the workpiece.

Development of the resist film can be performed by bringing the resist film into contact with a developer, for example. The method by which the resist film and the developer are brought into contact may be a method using a known technique such as immersion of the resist film in the developer or application of the developer onto the resist film without any specific limitations.

The developer can be selected as appropriate depending on properties of the previously described copolymer, for example. It is preferable that a developer in which the resist film that has not yet undergone the exposure step does not dissolve, but in which a highly soluble portion B of the resist film that has undergone the exposure step or the post exposure bake step can dissolve, is selected as the developer. Any known developer can be used as the developer without any specific limitations. Moreover, one developer may be used individually, or two or more developers may be used as a mixture in a freely selected ratio.

### (Rinsing Step)

In the presently disclosed method of forming a resist pattern, a step of removing the developer can be performed after the development step. Removal of the developer can be performed using a rinsing liquid, for example.

Water or a solution containing a typical organic solvent can be used as the rinsing liquid without any specific limitations so long as it is a liquid in which the resist pattern does not dissolve. In selection of the rinsing liquid, it is preferable to select a rinsing liquid that readily mixes with the developer.

### EXAMPLES

The following provides a more specific description of the present disclosure based on examples. However, the present disclosure is not limited to these examples.

Various measurements and evaluations in the examples and comparative examples were performed according to the following methods.

### <Attribute of Cross-Linker>

A judgement as to whether or not a cross-linker satisfied an attribute of “reacting in response to ionizing radiation or non-ionizing radiation having a wavelength of 300 nm or less” was made according to the following method. A cross-linker solution (concentration: 10 mass %; solvent: isoamyl acetate) was applied onto a silicon wafer, and solvent was caused to evaporate to produce a test specimen in a state without flow even when placed at rest. The thickness of the test specimen was measured and was taken to be T¹. The test specimen was irradiated for 400 μC/cm² with a 50 keV electron beam, was subsequently immersed in the same type of solvent as the solvent used to produce the cross-linker solution at room temperature (23° C.) for 1 minute, and was dried. The thickness T² of the dried test specimen was measured, and in a case in which the value of T²/T¹×100 was 50% or more, the cross-linker was judged to “react in response to ionizing radiation or non-ionizing radiation having a wavelength of 300 nm or less”.

Each of the cross-linkers used in the examples and comparative examples was soluble in isoamyl acetate, which was used as the solvent during the above. However, even supposing a case in which a cross-linker that differs from these cross-linkers and that is insoluble in isoamyl acetate is used, anisole or tetrahydrofuran can be used as the solvent in this case.

The results of judgements for the various cross-linkers used in the examples and comparative examples are shown in Tables 1 and 2.

### <Cross-Linking State in Resist Film>

A resist film formed in each example or comparative example was immersed in a solvent (same solvent as used in confirmation of the cross-linker attribute described above) at room temperature (23° C.) for 1 minute, and the thicknesses before and after immersion were compared in the same way as described above. As a result, it was confirmed that in Examples 1 to 18, the thickness after immersion was less than 50% and that cross-linking of the cross-linker in the resist film had not proceeded. Note that almost the same results were confirmed for Comparative Examples 1 to 5 as for Examples 1 to 18. On the other hand, it was confirmed in Comparative Example 6 that the thickness after immersion was 50% or more of the thickness before immersion and that a cross-linking reaction of the cross-linker had proceeded to a significant extent.

### <Exposure Margin>

The electron beam irradiation dose range with which formation of a resist pattern with a half-pitch (hp) of 25 nm was possible in “Resolution of resist pattern” described below was evaluated in accordance with the following standard.
AA: Electron beam irradiation dose range of 80 μC/cm² or more
A: Electron beam irradiation dose range of not less than 50 μC/cm² and less than 80 μC/cm²
B: Electron beam irradiation dose range of not less than 30 μC/cm² and less than 50 μC/cm²
C: Electron beam irradiation dose range of less than 30 μC/cm²

### <Resolution of Resist Pattern>

With respect to line-and-space patterns having half-pitches (hp) of 18 nm, 20 nm, 22 nm, 25 nm, and 30 nm that were formed in each example or comparative example, a visual check as to whether overall formation of a resist pattern at a given electron beam irradiation dose (within irradiated range of 10 μC/cm² to 600 μC/cm²) was possible was made regardless of quality of the pattern. Moreover, resist pattern resolution was evaluated in accordance with the following standard.
AA: Pattern can be formed with half-pitches (hp) of 18 nm, 20 nm, 22 nm, 25 nm, and 30 nm
A: Pattern can be formed with half-pitches (hp) of 20 nm, 22 nm, 25 nm, and 30 nm
B: Pattern can be formed with half-pitches (hp) of 22 nm, 25 nm, and 30 nm
C: Pattern can be formed with half-pitches (hp) of 25 nm and 30 nm, or pattern cannot be formed

### <Clarity>

The clarity of a resist pattern was evaluated using, as a subject, a resist pattern having a half-pitch (hp) of 25 nm that was formed in each example or comparative example. Specifically, clarity was evaluated based on the number of open/bridging defects that were present. Note that in evaluation of an “open defect”, a visual judgement was made as to whether or not a region with line width narrowing where a line portion appeared to be pinched by something was present in a resist pattern formed with a certain electron beam irradiation dose. Moreover, in evaluation of a “bridging defect (stochastic)”, a visual judgement was made as to whether or not a region where a space was not interposed between adjacent lines (i.e., a region where adjacent lines were joined) was present in a resist pattern formed with a certain electron beam irradiation dose.
AA: “Open/bridging defects” not observed in resist pattern
A: Very small number of “open/bridging defects” in resist pattern that is within permissible range
B: Small number of “open/bridging defects” in resist pattern that is within permissible range
C: Large number of “open/bridging defects” in resist pattern that is outside of permissible range, or pattern cannot be formed

### <Number-Average Molecular Weight, Weight-Average Molecular Weight, and Molecular Weight Distribution>

The number-average molecular weight (Mn) and the weight-average molecular weight (Mw) of a copolymer obtained in each example or comparative example were measured by gel permeation chromatography, and then the molecular weight distribution (Mw/Mn) of the copolymer was calculated.

Specifically, the number-average molecular weight (Mn) and the weight-average molecular weight (Mw) of the copolymer were determined as standard polystyrene-equivalent values using a gel permeation chromatograph (HLC-8420 produced by Tosoh Corporation) with tetrahydrofuran as an eluent solvent. The molecular weight distribution (Mw/Mn) was then calculated.

### Synthesis Example 1

### <Production of Copolymer A>

### [Synthesis of Polymerized Product]

A glass vessel was charged with a monomer composition (monomer concentration: 40 mass %) containing 10.00 g of methyl α-chloroacrylate (ACAM) as a monomer (a), 22.93 g of α-methylstyrene (AMS) as a monomer (b), 49.45 g of cyclopentanone (CPN) as a solvent, and 0.0364 g of azobisisobutyronitrile (AIBN) as a polymerization initiator. The glass vessel was tightly sealed and purged with nitrogen, and was then stirred under a nitrogen atmosphere inside a 75° C. constant-temperature tank for 48 hours. Thereafter, the glass container was returned to room temperature, the inside of the glass container was opened to the atmosphere, and then 10 g of tetrahydrofuran (THF) was added to the resultant solution. Next, the solution to which 10 g of THF had been added was added dropwise to 100 g of methanol to cause precipitation of a polymerized product. Thereafter, the solution containing the polymerized product that had precipitated was filtered using a Kiriyama funnel to obtain a white coagulated material (polymerized product).

### [Purification of Polymerized Product]

Next, the obtained polymerized product was dissolved in 10 g of THE, the resultant solution was added dropwise to 100 g of methanol (MeOH), and solid content that had precipitated was filtered off. The obtained solid content was dissolved in 10 g of THE, the resultant solution was added dropwise to 100 g of methanol (MeOH) (i.e., reprecipitation purification of adding a THF solution dropwise to methanol was performed twice), and a white coagulated material (copolymer comprising α-methylstyrene units and methyl α-chloroacrylate units) was caused to precipitate. Thereafter, the solution containing the copolymer that had precipitated was filtered using a Kiriyama funnel to obtain a white copolymer A. The obtained polymerized product had a weight-average molecular weight (Mw) of 55,000, a number-average molecular weight (Mn) of 29,000, and a molecular weight distribution (Mw/Mn) of 1.90.

### Synthesis Example 2

### <Production of Copolymer B>

### [Synthesis of Polymerized Product]

A glass ampoule in which a stirrer had been placed was charged with 3.00 g of 1-phenyl-1-trifluoromethyl-2,2,2-trifluoroethyl α-chloroacrylate as a monomer (a), 2.493 g of α-methylstyrene as a monomer (b), and 0.0039534 g of azobisisobutyronitrile as a polymerization initiator. The ampoule was tightly sealed and oxygen was removed from the system through 10 repetitions of pressurization and depressurization with nitrogen gas.

The system was then heated to 78° C. and a reaction was carried out for 3.5 hours. Next, 10 g of tetrahydrofuran was added to the system, and then the resultant solution was added dropwise to 300 mL of methanol to cause precipitation of a polymerized product. Thereafter, the polymerized product that had precipitated was collected by filtration.

### [Purification of Polymerized Product]

Next, the obtained polymerized product was dissolved in 100 g of tetrahydrofuran (THF), and then the resultant solution was added dropwise to a mixed solvent of 150 g of THF and 850 g of methanol (MeOH) to cause precipitation of a white coagulated material (copolymer comprising α-methylstyrene units and 1-phenyl-1-trifluoromethyl-2,2,2-trifluoroethyl α-chloroacrylate units). Thereafter, the solution containing the coagulated material that had precipitated was filtered using a Kiriyama funnel to obtain a white copolymer B.

The copolymer B comprised 50 mol % of α-methylstyrene units and 50 mol % of 1-phenyl-1-trifluoromethyl-2,2,2-trifluoroethyl α-chloroacrylate units. The obtained polymerized product had a weight-average molecular weight (Mw) of 62,344, a number-average molecular weight (Mn) of 39,845, and a molecular weight distribution (Mw/Mn) of 1.565.

### Example 1

### <Production of Positive Resist Composition (Composition 1)>

A composition 1 was produced by mixing 100 parts by mass of the copolymer A synthesized in Synthesis Example 1, 5 parts by mass of a mixture of ethylene oxide-modified isocyanurate diacrylate and ethylene oxide-modified isocyanurate triacrylate (produced by Toagosei Co., Ltd.; product name: ARONIX® M-315; mixture of difunctional compound and trifunctional compound; denoted as cross-linker A in Tables 1 and 2) as a cross-linker, and 5,143 parts by mass of anisole as a solvent and then filtering the resultant mixed solution using a membrane filter having a pore diameter of 20 nm.

### <Formation of Resist Pattern>

### —Resist Film Formation Step—

A spin coater (MS-A150 produced by Mikasa Co., Ltd.) was used to apply the positive resist composition produced in Synthesis Example 1 onto a 4-inch silicon wafer such as to have a thickness of 30 nm to thereby form a coating layer (application step). The coating layer was subjected to 3 minutes of heated drying (prebaking) using a hot plate having a temperature of 180° C. in order to remove the solvent from the formed coating layer and thereby form a positive resist film on the silicon wafer (drying step).

### —Exposure Step—

Next, an electron beam lithography tool (ELS-S50 produced by Elionix Inc.) was used to expose the resist film with an accelerating voltage of 50 kV and an electron beam irradiation dose of 10 μC/cm² to 600 μC/cm² so as to write line-and-space patterns with half-pitches (hp) of 18 nm, 20 nm, 22 nm, 25 nm, and 30 nm.

### —Development Step—

Development treatment was subsequently performed at a temperature of 23° C. for 1 minute using hexyl acetate (ZED-N60 produced by Zeon Corporation) as a resist developer, and then 10 seconds of rinsing was performed using isopropyl alcohol as a rinsing liquid to form a resist pattern.

### —Evaluation—

The formed resist pattern was observed (×100,000 magnification) using a scanning electron microscope (SEM), and the exposure margin, resolution of the resist pattern, and clarity (open/bridging defects) were evaluated as previously described.

### Examples 2 and 3

A composition 2 (Example 2) and a composition 3 (Example 3) were each produced in the same way as in Example 1 with the exception that the amount of the cross-linker was changed to 15 parts (Example 2) or 25 parts (Example 3), and then a resist pattern was formed in the same way as in Example 1 and various evaluations were performed in the same way as in Example 1. The results are shown in Table 1.

### Example 4

The composition 2 was used to perform steps from the resist film formation step through to the exposure step in the same way as in Example 1, and then a post exposure bake step of heating the resist film for 1 minute on a hot plate having a temperature of 120° C. was performed before the development step. Thereafter, the development step was performed in the same way as in Example 1 and various evaluations were performed in the same way as in Example 1. The results are shown in Table 1.

### Example 5

### <Production of Positive Resist Composition (Composition 4)>

A composition 4 was produced by mixing 100 parts by mass of the copolymer B produced in Synthesis Example 2, 5 parts by mass of a mixture of ethylene oxide-modified isocyanurate diacrylate and ethylene oxide-modified isocyanurate triacrylate (produced by Toagosei Co., Ltd.; product name: ARONIX M-315; mixture of difunctional compound and trifunctional compound; denoted as cross-linker A in Tables 1 and 2) as a cross-linker, and 5,143 parts by mass of isoamyl acetate as a solvent and then filtering the resultant mixed solution using a membrane filter having a pore diameter of 20 nm.

### <Formation of Resist Pattern>

Heated drying (prebaking) for removing solvent from the coating layer in the resist film formation step was performed by a hot plate having a temperature of 170° C. for 1 minute. Moreover, the developer used in the development step was changed to isopropyl alcohol, and the rinsing operation was omitted. With the exception of these points, a resist pattern was formed in the same way as in Example 1. Various evaluations were performed in the same way as in Example 1 with respect to the obtained resist pattern. The results are shown in Table 1.

### Examples 6 and 7

A composition 5 (Example 6) and a composition 6 (Example 7) were produced in the same way as in Example 5 with the exception that the amount of the cross-linker was changed to 15 parts (Example 6) or 25 parts (Example 7), and then a resist pattern was formed in the same way as in Example 1 and various evaluations were performed in the same way as in Example 1. The results are shown in Table 1.

### Example 8

The composition 5 was used to perform steps from the resist film formation step through to the exposure step in the same way as in Example 6, and then a post exposure bake step of heating the resist film for 1 minute on a hot plate having a temperature of 120° C. was performed before the development step. Thereafter, the development step was performed in the same way as in Example 1 and various evaluations were performed in the same way as in Example 1. The results are shown in Table 1.

### Example 9

A composition 7 was produced in the same way as in Example 1 with the exception that the cross-linker compounded in the resist composition was changed to 15 parts of trimethylolpropane triacrylate (produced by Toagosei Co., Ltd.; product name: ARONIX® M-309; trifunctional; denoted as cross-linker B in Tables 1 and 2), and then a resist pattern was formed and various evaluations were performed in the same way as in Example 1. The results are shown in Table 1.

### Example 10

A composition 8 was produced, a resist pattern was formed, and various evaluations were performed in the same way as in Example 1 with the exception that the cross-linker compounded in the resist composition was changed to 10 parts of a mixture of dipentaerythritol pentaacrylate and dipentaerythritol hexaacrylate (produced by Toagosei Co., Ltd.; product name: ARONIX® M-403; pentafunctional; denoted as cross-linker C in Tables 1 and 2). The results are shown in Table 1.

### Example 11

A composition 9 was produced, a resist pattern was formed, and various evaluations were performed in the same way as in Example 5 with the exception that the cross-linker compounded in the resist composition was changed to 20 parts of polyethylene glycol diacrylate (produced by Toagosei Co., Ltd.; product name: ARONIX® M-240; difunctional; denoted as cross-linker D in Tables 1 and 2). The results are shown in Table 1.

### Example 12

A composition 10 was produced, a resist pattern was formed, and various evaluations were performed in the same way as in Example 1 with the exception that the cross-linker compounded in the resist composition was changed to 15 parts of triallyl isocyanurate (produced by Mitsubishi Chemical Corporation; product name: TAIC; trifunctional; denoted as cross-linker H in Tables 1 and 2). The results are shown in Table 1.

### Example 13

A composition 11 was produced, a resist pattern was formed, and various evaluations were performed in the same way as in Example 5 with the exception that the cross-linker compounded in the resist composition was changed to 15 parts of triethylene glycol divinyl ether (produced by Nippon Carbide Industries Co., Ltd.; product name: TEGDVE; difunctional; denoted as cross-linker I in Tables 1 and 2). The results are shown in Table 1.

### Example 14

Polymethyl methacrylate (denoted as polymer C in Table 1; polystyrene-equivalent weight-average molecular weight: 40,000) was used instead of a copolymer as a polymer compounded in a resist composition.

A composition 12 was produced by mixing 100 parts by mass of this polymer C, 10 parts by mass of a mixture of ethylene oxide-modified isocyanurate diacrylate and ethylene oxide-modified isocyanurate triacrylate (produced by Toagosei Co., Ltd.; product name: ARONIX® M-315; mixture of difunctional compound and trifunctional compound; denoted as cross-linker A in Tables 1 and 2) as a cross-linker, and 5,634 parts by mass of cellosolve acetate as a solvent and then filtering the resultant mixed solution using a membrane filter having a pore diameter of 20 nm.

In formation of a resist pattern using the composition 12, heated drying (prebaking) for removing solvent from the coating layer in the resist film formation step was performed by a hot plate having a temperature of 150° C. for 3 minutes. Moreover, the developer used in the development step was changed to a mixture of methyl isobutyl ketone and isopropyl alcohol (mixing ratio by mass of MIBK:IPA=1:1). With the exception of these points, a resist pattern was formed in the same way as in Example 1. Various evaluations were performed in the same way as in Example 1 with respect to the obtained resist pattern. The results are shown in Table 1.

### Example 15

A composition 13 was produced, a resist pattern was formed, and various evaluations were performed in the same way as in Example 5 with the exception that the cross-linker compounded in the resist composition was changed to 35 parts of triallyl isocyanurate (produced by Mitsubishi Chemical Corporation; product name: TAIC; trifunctional; denoted as cross-linker H in Tables 1 and 2). The results are shown in Table 1.

### Example 16

A composition 14 was produced, a resist pattern was formed, and various evaluations were performed in the same way as in Example 5 with the exception that the cross-linker compounded in the resist composition was changed to 40 parts of phenoxy polyethylene glycol acrylate (produced by Shin-Nakamura Chemical Co., Ltd.; product name: NK ESTER AMP20GY; monofunctional; denoted as cross-linker E in Tables 1 and 2). The results are shown in Table 1.

### Example 17

A composition 15 was produced, a resist pattern was formed, and various evaluations were performed in the same way as in Example 5 with the exception that the cross-linker compounded in the resist composition was changed to 40 parts of ethoxylated o-phenylphenol acrylate (produced by Shin-Nakamura Chemical Co., Ltd.; product name: NK ESTER A-LEN-10; monofunctional; denoted as cross-linker F in Tables 1 and 2). The results are shown in Table 1.

### Example 18

A composition 16 was produced, a resist pattern was formed, and various evaluations were performed in the same way as in Example 5 with the exception that the cross-linker compounded in the resist composition was changed to 40 parts of 2-acryloyloxyethyl succinate (produced by Shin-Nakamura Chemical Co., Ltd.; product name: NK ESTER A-SA; monofunctional; denoted as cross-linker G in Tables 1 and 2). The results are shown in Table 1.

### Comparative Example 1

A composition 17 was produced, a resist pattern was formed, and various evaluations were performed in the same way as in Example 1 with the exception that a cross-linker was not compounded. The results are shown in Table 2.

### Comparative Example 2

A composition 18 was produced, a resist pattern was formed, and various evaluations were performed in the same way as in Example 5 with the exception that a cross-linker was not compounded. The results are shown in Table 2.

### Comparative Example 3

Steps from the resist film formation step through to the exposure step were performed in the same way as in Example 1 with the exception that a composition 17 produced in the same way as in Comparative Example 1 was used and that heated drying (prebaking) for removing solvent from the coating layer in the resist film formation step was performed by a hot plate having a temperature of 180° C. for 3 minutes. A post exposure bake step of heating the resist film using a hot plate having a temperature of 120° C. was subsequently performed for 1 minute before the development step. Thereafter, the development step was performed in the same way as in Example 1 and various evaluations were performed in the same way as in Example 1. The results are shown in Table 2.

### Comparative Example 4

A composition 19 was produced, a resist pattern was formed, and various evaluations were performed in the same way as in Example 14 with the exception that a cross-linker was not compounded. The results are shown in Table 2.

### Comparative Example 5

A composition 20 was produced in the same way as in Example 1 with the exception that the cross-linker compounded in the resist composition was changed to 30 parts of a bisphenol A-type epoxy compound (produced by Mitsubishi Chemical Corporation; product name: jER 828EL; denoted as cross-linker J in Tables 1 and 2), and then a resist pattern was formed and various evaluations were performed in the same way as in Example 1 using this composition 20. The results are shown in Table 2.

### Comparative Example 6

A composition 20 was produced in the same way as in Comparative Example 5, and then 2 parts of 1-benzyl-2-phenylimidazole (produced by Shikoku Chemicals Corporation; product name: CUREZOL® 1B2PZ (CUREZOL is a registered trademark in Japan, other countries, or both)), which is a curing agent, was further compounded therewith to obtain a composition 21. This composition was used to form a coating layer in the same way as in Example 1, and the coating layer was heated by a hot plate at a temperature of 150° C. for 2 hours so as to not only remove solvent from the coating layer, but also cause a cross-linking reaction of the cross-linker J to proceed. A resist film that was obtained in this manner was used to form a resist pattern and perform various evaluations in the same way as in Comparative Example 5. The results are shown in Table 2.

TABLE 1

| | | Examples | | | | | | | | | |
|---|---|---|---|---|---|---|---|---|---|---|---|
| | | 1 | 2 | 3 | 4 | 5 | 6 | 7 | 8 | 9 | 10 |
| Resist | Composition | Compo- | Compo- | Compo- | Compo- | Compo- | Compo- | Compo- | Compo- | Compo- | Compo- |
| composition | no. | sition | sition | sition | sition | sition | sition | sition | sition | sition | sition |
| [parts by | | 1 | 2 | 3 | 2 | 4 | 5 | 6 | 5 | 7 | 8 |
| mass] | Polymer type | Co- | Co- | Co- | Co- | Co- | Co- | Co- | Co- | Co- | Co- |
| | | polymer | polymer | polymer | polymer | polymer | polymer | polymer | polymer | polymer | polymer |
| | | A | A | A | A | B | B | B | B | A | A |
| | Cross-linker | Satis- | Satis- | Satis- | Satis- | Satis- | Satis- | Satis- | Satis- | Satis- | Satis- |
| | attribute | fied | fied | fied | fied | fied | fied | fied | fied | fied | fied |
| | Cross-linker A | 5 | 15 | 25 | 15 | 5 | 15 | 25 | 15 | — | — |
| | (acrylate 1) | | | | | | | | | | |
| | Cross-linker B | — | — | — | — | — | — | — | — | 15 | — |
| | (acrylate 2) | | | | | | | | | | |
| | Cross-linker C | — | — | — | — | — | — | — | — | — | 10 |
| | (acrylate 3) | | | | | | | | | | |
| | Cross-linker D | — | — | — | — | — | — | — | — | — | — |
| | (acrylate 4) | | | | | | | | | | |
| | Cross-linker E | — | — | — | — | — | — | — | — | — | — |
| | (acrylate 5) | | | | | | | | | | |
| | Cross-linker F | — | — | — | — | — | — | — | — | — | — |
| | (acrylate 6) | | | | | | | | | | |
| | Cross-linker G | — | — | — | — | — | — | — | — | — | — |
| | (acrylate 7) | | | | | | | | | | |
| | Cross-linker H | — | — | — | — | — | — | — | — | — | — |
| | (allyl) | | | | | | | | | | |
| | Cross-linker I | — | — | — | — | — | — | — | — | — | — |
| | (vinyl) | | | | | | | | | | |
| | Cross-linker J | — | — | — | — | — | — | — | — | — | — |
| | (epoxy) | | | | | | | | | | |
| | Curing agent | — | — | — | — | — | — | — | — | — | — |
| Resist | Prebake step | 180° | 180° | 180° | 180° | 170° | 170° | 170° | 170° | 180° | 180° |
| pattern | | C./ | C./ | C./ | C./ | C./ | C./ | C./ | C./ | C./ | C./ |
| formation | | 3 min | 3 min | 3 min | 3 min | 1 min | 1 min | 1 min | 1 min | 3 min | 3 min |
| method | Exposure step | EB | EB | EB | EB | EB | EB | EB | EB | EB | EB |
| | | litho- | litho- | litho- | litho- | litho- | litho- | litho- | litho- | litho- | litho- |
| | | graphy | graphy | graphy | graphy | graphy | graphy | graphy | graphy | graphy | graphy |
| | Post exposure | No | No | No | Yes | No | No | No | Yes | No | No |
| | bake step | | | | (120° C./ | | | | (120° C./ | | |
| | | | | | 1 min) | | | | 1 min) | | |
| | Developer in | ZED-N60 | ZED-N60 | ZED-N60 | ZED-N60 | IPA | IPA | IPA | IPA | ZED-N60 | ZED-N60 |
| | development step | | | | | | | | | | |
| Evaluation | Exposure margin | A | AA | A | AA | A | AA | A | AA | AA | A |
| | Resolution | A | AA | A | AA | A | AA | A | AA | AA | A |
| | Clarity | AA | AA | A | AA | A | AA | AA | AA | AA | A |
| | (open/bridging | | | | | | | | | | |
| | defects) | | | | | | | | | | |

| | | Examples | | | | | | | |
|---|---|---|---|---|---|---|---|---|---|
| | | 11 | 12 | 13 | 14 | 15 | 16 | 17 | 18 |
| Resist | Composition | Compo- | Compo- | Compo- | Compo- | Compo- | Compo- | Compo- | Compo- |
| composition | no. | sition | sition | sition | sition | sition | sition | sition | sition |
| [parts by | | 9 | 10 | 11 | 12 | 13 | 14 | 15 | 16 |
| mass] | Polymer type | Co- | Co- | Co- | Polymer | Co- | Co- | Co- | Co- |
| | | polymer | polymer | polymer | C | polymer | polymer | polymer | polymer |
| | | B | A | B | | B | B | B | B |
| | Cross-linker | Satis- | Satis- | Satis- | Satis- | Satis- | Satis- | Satis- | Satis- |
| | attribute | fied | fied | fied | fied | fied | fied | fied | fied |
| | Cross-linker A | — | — | — | 10 | — | — | — | — |
| | (acrylate 1) | | | | | | | | |
| | Cross-linker B | — | — | — | — | — | — | — | — |
| | (acrylate 2) | | | | | | | | |
| | Cross-linker C | — | — | — | — | — | — | — | — |
| | (acrylate 3) | | | | | | | | |
| | Cross-linker D | 20 | — | — | — | — | — | — | — |
| | (acrylate 4) | | | | | | | | |
| | Cross-linker E | — | — | — | — | — | 40 | — | — |
| | (acrylate 5) | | | | | | | | |
| | Cross-linker F | — | — | — | — | — | — | 40 | — |
| | (acrylate 6) | | | | | | | | |
| | Cross-linker G | — | — | — | — | — | — | — | 40 |
| | (acrylate 7) | | | | | | | | |
| | Cross-linker H | — | 15 | — | — | 35 | — | — | — |
| | (allyl) | | | | | | | | |
| | Cross-linker I | — | — | 15 | — | — | — | — | — |
| | (vinyl) | | | | | | | | |
| | Cross-linker J | — | — | — | — | — | — | — | — |
| | (epoxy) | | | | | | | | |
| | Curing agent | — | — | — | — | — | — | — | — |
| Resist | Prebake step | 170° | 180° | 170° | 150° | 170° | 170° | 170° | 170° |
| pattern | | C./ | C./ | C./ | C./ | C./ | C./ | C./ | C./ |
| formation | | 1 min | 3 min | 1 min | 3 min | 1 min | 1 min | 1 min | 1 min |
| method | Exposure step | EB | EB | EB | EB | EB | EB | EB | EB |
| | | litho- | litho- | litho- | litho- | litho- | litho- | litho- | litho- |
| | | graphy | graphy | graphy | graphy | graphy | graphy | graphy | graphy |
| | Post exposure | No | No | No | No | No | No | No | No |
| | bake step | | | | | | | | |
| | Developer in | IPA | ZED-N60 | IPA | MIBK:IPA = | IPA | IPA | IPA | IPA |
| | development step | | | | 1:1 | | | | |
| Evaluation | Exposure margin | AA | AA | A | A | AA | A | A | A |
| | Resolution | AA | A | A | B | A | A | A | A |
| | Clarity | AA | A | A | B | A | A | A | A |
| | (open/bridging | | | | | | | | |
| | defects) | | | | | | | | |

TABLE 2

| | | Comparative examples | | | | | |
|---|---|---|---|---|---|---|---|
| | | 1 | 2 | 3 | 4 | 5 | 6 |
| Resist | Composition no. | Composition 17 | Composition 18 | Composition 17 | Composition 19 | Composition 20 | Composition 21 |
| composition | Polymer type | Copolymer A | Copolymer B | Copolymer A | Polymer C | Copolymer A | Copolymer A |
| [parts by | Cross-linker | — | — | — | — | Not satisfied | Not satisfied |
| mass] | attribute | | | | | | |
| | Cross-linker A | — | — | — | — | — | — |
| | (acrylate 1) | | | | | | |
| | Cross-linker B | — | — | — | — | — | — |
| | (acrylate 2) | | | | | | |
| | Cross-linker C | — | — | — | — | — | — |
| | (acrylate 3) | | | | | | |
| | Cross-linker D | — | — | — | — | — | — |
| | (acrylate 4) | | | | | | |
| | Cross-linker E | — | — | — | — | — | — |
| | (acrylate 5) | | | | | | |
| | Cross-linker F | — | — | — | — | — | — |
| | (acrylate 6) | | | | | | |
| | Cross-linker G | — | — | — | — | — | — |
| | (acrylate 7) | | | | | | |
| | Cross-linker H | — | — | — | — | — | — |
| | (allyl) | | | | | | |
| | Cross-linker I | — | — | — | — | — | — |
| | (vinyl) | | | | | | |
| | Cross-linker J | — | — | — | — | 30 | 30 |
| | (epoxy) | | | | | | |
| | Curing agent | — | — | — | — | — | 2 |
| Resist | Prebake step | 180° C./3 min | 170° C./1 min | 180° C./3 min | 150° C./3 min | 180° C./3 min | 150° C./2 hr |
| pattern | Exposure step | EB lithography | EB lithography | EB lithography | EB lithography | EB lithography | EB lithography |
| formation | Post exposure | No | No | Yes | No | No | No |
| method | bake step | | | (120° C./1 min) | | | |
| | Developer in | ZED-N60 | IPA | ZED-N60 | MIBK:IPA = | ZED-N60 | ZED-N60 |
| | development step | | | | 1:1 | | |
| Evaluation | Exposure margin | B | B | B | B | C | C |
| | Resolution | A | A | A | C | B | C |
| | Clarity | B | B | B | C | C | C |
| | (open/bridging | | | | | | |
| | defects) | | | | | | |

It can be seen from the results shown in Table 1 and Table 2 that the exposure margin of a resist film was wide and that a clear resist pattern having few defects could be formed in Examples 1 to 18 in which the used resist composition contained a cross-linker that reacts in response to ionizing radiation or non-ionizing radiation having a wavelength of 300 nm or less. In contrast, it can be seen that the exposure margin of a resist film was narrow and that a clear resist pattern could not be formed in Comparative Examples 1 to 4 in which a cross-linker was not compounded at all and in Comparative Examples 5 and 6 in which a cross-linker was compounded, but in which the compounded cross-linker did not satisfy a specific attribute.

### INDUSTRIAL APPLICABILITY

According to the present disclosure, it is possible to provide a resist composition and a method of forming a resist pattern that have a wide exposure margin and enable the formation of a clear resist pattern having few defects.

1. A resist composition comprising:
a cross-linker that reacts in response to ionizing radiation or non-ionizing radiation having a wavelength of 300 nm or less;
a solvent; and
a polymer.

2. The resist composition according to claim 1, wherein the polymer is a main chain scission-type polymer.

3. The resist composition according to claim 1, wherein the polymer is a copolymer including:
a monomer unit (A) represented by general formula (I), shown below, 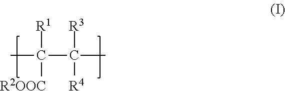
where, in general formula (I), R¹ is a halogen atom or a halogen atom-substituted alkyl group, R² is a hydrogen atom or an organic group including not fewer than 0 and not more than 11 fluorine atoms, and R³ and R⁴ are each a hydrogen atom, a halogen atom, an unsubstituted alkyl group, or a halogen atom-substituted alkyl group and may be the same as or different from each other; and
a monomer unit (B) represented by general formula (II), shown below, 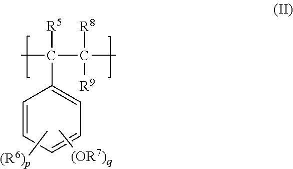
where, in general formula (II), R⁵, R⁶, R⁸, and R⁹ are each a hydrogen atom, a halogen atom, an unsubstituted alkyl group, or a halogen atom-substituted alkyl group and may be the same as or different from one another, R⁷ is a hydrogen atom, an unsubstituted alkyl group, or a halogen atom-substituted alkyl group, p and q are each an integer of not less than 0 and not more than 5, and p+q=5.

4. The resist composition according to claim 1, wherein the cross-linker includes an unsaturated bond.

5. The resist composition according to claim 4, wherein the cross-linker includes not fewer than 1 and not more than 10 of the unsaturated bond.

6. The resist composition according to claim 4, wherein the unsaturated bond of the cross-linker is an unsaturated bond included in a vinyl group, a (meth)acrylate group, or an allyl group.

7. The resist composition according to claim 1, wherein the cross-linker is included in a proportion of not less than 1 part by mass and not more than 60 parts by mass relative to 100 parts by mass of the polymer.

8. A method of forming a resist pattern comprising:
performing resist film formation by applying a resist composition containing a cross-linker that reacts in response to ionizing radiation or non-ionizing radiation having a wavelength of 300 nm or less, a solvent, and a polymer onto a substrate to obtain a coating layer, and removing the solvent from the coating layer to form a resist film; and
performing exposure by exposing the resist film formed in the resist film formation using ionizing radiation or non-ionizing radiation having a wavelength of 300 nm or less as exposure light and causing a cross-linking reaction to proceed through the cross-linker while forming a latent pattern.

9. The method of forming a resist pattern according to claim 8, wherein the polymer is a main chain scission-type polymer, and the cross-linking reaction and a main chain scission reaction of the polymer proceed concurrently in the exposure.
